(19) United States
(12) Patent Application Publication
(10) Pub. No.: US 2026/0143684 A1
(43) Pub. Date: May 21, 2026

(54) TRANSISTOR, 3D STACKED SEMICONDUCTOR DEVICE AND MANUFACTURING METHOD THEREOF, AND ELECTRONIC DEVICE

(71) Applicant: BEIJING SUPERSTRING ACADEMY OF MEMORY TECHNOLOGY, Beijing (CN)

(72) Inventors: Xuezheng Ai, Beijing (CN); Xiangsheng Wang, Beijing (CN); Guilei Wang, Beijing (CN); Chao Zhao, Beijing (CN); Jin Dai, Beijing (CN); Wenhua Gui, Beijing (CN); Wei Yu, Beijing (CN)

(73) Assignee: BEIJING SUPERSTRING ACADEMY OF MEMORY TECHNOLOGY, Beijing (CN)

(21) Appl. No.: 18/697,094

(22) PCT Filed: May 24, 2023
(86) PCT No.: PCT/CN2023/096117

§ 371 Date: Mar. 29, 2024

(30) Foreign Application Priority Data
Mar. 23, 2023 (CN) 202310289097.1

(51) Int. Cl. H10B 12/00; H10D 1/68; H10D 62/17

(52) U.S. Cl. CPC H10B 12/482; H10B 12/05; H10B 12/488; H10D 1/714; H10D 62/235; H10B 12/00

(57) ABSTRACT

Provided are a transistor, a 3D stacked semiconductor device, a manufacturing method thereof, and an electronic device. The transistor includes a first electrode and a second electrode arranged on a substrate, a semiconductor layer arranged between the first electrode and the second electrode, and a gate electrode insulated from the semiconductor layer; the first electrode and the second electrode are separated in a first direction parallel to the substrate; the gate electrode extends along a second direction parallel to the substrate, the gate electrode includes a sidewall extending along the second direction and two end surfaces, one end surface is configured to be connected with a word line; at least a portion of the sidewall of the gate electrode is surrounded by a semiconductor layer; the first direction intersects with the second direction.

### CROSS-REFERENCE TO RELATED APPLICATIONS

The present application is a U.S. National Phase Entry of International Application No. PCT/CN2023/096117 having an international filing date of May 24, 2023, which claims priority to Chinese Patent Application No. 202310289097.1 filed to the CNIPA on Mar. 23, 2023, the contents of which are understood to be incorporated in the present disclosure by reference.

### TECHNICAL FIELD

Embodiments of the present disclosure relate to, but are not limited to, the field of design and manufacture of semiconductor devices, in particular to a transistor, a 3D stacked semiconductor device, a manufacturing method thereof, and an electronic device.

### BACKGROUND

Semiconductor memory may be divided into volatile memory (RAM, including DRAM and SRAM, etc.) and non-volatile memory (ROM and non-ROM).

Taking DRAM as an example, conventional known DRAM has multiple repeated “memory cells”, each of which has a capacitor and a transistor. The capacitor may store 1-bit data, and after charging and discharging, the amount of charges stored in the capacitor may correspond to binary data “1” and “0”, respectively. The Transistor is a switch that controls the charging and discharging of the capacitor.

In order to reduce the cost of products as much as possible, people want to make as many memory cells as possible on a limited substrate. Since Moore's Law came out, the industry has proposed various semiconductor structure designs and process optimizations to meet people's demands for current products.

### SUMMARY

The following is a summary of the subject matters described in detail in this document. This summary is not intended to limit the scope of protection of the present disclosure.

An embodiment of the present disclosure provides a transistor, including: a first electrode and a second electrode arranged on a substrate, a semiconductor layer arranged between the first electrode and the second electrode, and a gate electrode insulated from the semiconductor layer. The first electrode and the second electrode are separated in a first direction parallel to the substrate; the gate electrode includes a side wall and two end surfaces, wherein one end surface of the two end surfaces is configured to be connected with a word line; at least a portion of the gate electrode is surrounded by the semiconductor layer; and an extension direction of the gate electrode intersects with an extension direction of the word line.

In an exemplary embodiment of the present disclosure, the gate electrode may extend along a second direction parallel to the substrate, and the first direction intersects with the second direction; and the word line may extend along the first direction or a direction perpendicular to the substrate.

In an exemplary embodiment of the present disclosure, the other end surface of the gate electrode may be surrounded by the semiconductor layer.

In an exemplary embodiment of the present disclosure, the semiconductor layer surrounding the gate electrode may form a hollow tubular structure; the tubular structure has a side surface, a bottom surface and an opening, wherein the side surface includes two separated electrode contact regions, which are respectively in contact with the first electrode and the second electrode, and a region of the side surface and the bottom surface of the tubular structure located between the first electrode and the second electrode is a channel region.

In an exemplary embodiment of the present disclosure, the gate electrode may extend to the bottom surface of the tubular structure through an opening of the tubular structure and is insulated from the tubular structure through a gate insulation layer.

In an exemplary embodiment of the present disclosure, the first electrode and the second electrode may be located in a same conductive layer parallel to the substrate, and an outer surface of a channel region of the semiconductor layer is located in a same horizontal plane as an outer surface of an adjacent first and/or second electrode.

In an exemplary embodiment of the present disclosure, a material of the semiconductor layer may be a metal oxide semiconductor material.

An embodiment of the present disclosure also provides a 3D stacked semiconductor device, wherein the semiconductor device includes: a word line; and a plurality of memory cells, distributed in different layers, and stacked periodically along a direction perpendicular to a substrate; wherein each layer includes a plurality of columns of memory cells, and a memory cell includes a transistor; the transistor includes a first electrode, a second electrode, a semiconductor layer arranged between the first electrode and the second electrode, and a gate electrode; the first electrode and the second electrode are separated in a first direction parallel to the substrate; the gate electrode includes a side wall and two end surfaces, one end surface is configured to be connected with the word line, and the other end surface extends into a hollow annular semiconductor layer; and an extension direction of the gate electrode intersects with an extension direction of the word line.

In an exemplary embodiment of the present disclosure, the end surface of the gate electrode extending into the semiconductor layer may be surrounded by the semiconductor layer.

In an exemplary embodiment of the present disclosure, the semiconductor layer surrounding the gate electrode may form a hollow tubular structure, and the tubular structure has a side surface, a bottom surface and an opening, wherein the side surface includes two separated electrode contact regions, which are respectively in contact with the first electrode and the second electrode, and the region of the side surface and the bottom surface of the tubular structure located between the first electrode and the second electrode is a channel region.

In an exemplary embodiment of the present disclosure, the gate electrode may extend to the bottom surface of the tubular structure through the opening of the tubular structure.

In an exemplary embodiment of the present disclosure, the gate electrode may extend in a second direction parallel to the substrate, and the first direction intersects with the second direction; the word line may extend in a direction perpendicular to the substrate; gate electrodes of transistors of a column of memory cells located in different layers are connected with a same word line; and the semiconductor device may further include a plurality of bit lines extending along the second direction; and transistors of a column of memory cells located on a same layer and arranged along the second direction are connected to a same bit line.

In an exemplary embodiment of the present disclosure, the gate electrode may extend in a second direction parallel to the substrate, and the first direction intersects with the second direction; the word line may extend along the second direction; gate electrodes of transistors of a column of memory cells located in a same layer and arranged along the second direction are connected with a same word line; and the 3D stacked semiconductor device may also include a plurality of bit lines extending along a direction perpendicular to the substrate; and transistors of a column of memory cells located in different layers are connected to a same bit line.

An embodiment of the disclosure also provides a method for manufacturing a 3D stacked semiconductor device. The 3D stacked semiconductor device includes: a word line; a plurality of memory cells, distributed in different layers, and stacked periodically along a direction perpendicular to the substrate. Each layer includes a plurality of columns of memory cells, and a memory cell includes a transistor; the transistor includes a first electrode, a second electrode, a semiconductor layer arranged between the first electrode and the second electrode, and a gate electrode; the first electrode and the second electrode are separated in a first direction parallel to the substrate; the gate electrode extends along a second direction in a plane parallel to the substrate, and the gate electrode includes a sidewall extending along the second direction and two end surfaces, wherein one end surface is configured to be connected with a word line, and the other end surface extends into a hollow annular semiconductor layer; the first direction intersects with the second direction; an extension direction of the gate electrode intersects with an extension direction of the word line.

The method includes: forming a first electrode and a second electrode of a transistor on the substrate; forming a bit line connected to a plurality of second electrodes; forming a hollow annular semiconductor layer between the first electrode and the second electrode and a gate electrode with one end surface extending into the semiconductor layer; and forming a word line connected to the other end surfaces of a plurality of gate electrodes after the gate electrode are formed, and making an extension direction of the word line be intersected with an extension direction of the gate electrodes.

In an exemplary embodiment of the present disclosure, forming the first electrode and the second electrode of the transistor on the substrate and forming the bit line connected to a plurality of the second electrodes may include:
sequentially and alternately depositing first insulation layers and second insulation layers on the substrate;
performing a patterning etching on the first insulation layers and the second insulation layers, wherein a patterned first insulation layer and a patterned second insulation layer include a dummy bit line region extending along the second direction, a dummy electrode region extending from a side of the dummy bit line region towards the first direction, a dummy channel and gate region extending from a side of the dummy electrode region towards the second direction; wherein the dummy electrode region includes a first electrode region located between two adjacent dummy channel and gate regions, and a second electrode region located between the dummy bit line region, and the dummy channel and gate region; one end of the dummy channel and gate region is connected with the dummy electrode region;
etching to remove a patterned second insulation layer of the first electrode region, obtaining a first electrode groove, and forming the first electrode in the first electrode groove; and
etching to remove patterned second insulation layers of the second electrode region and the dummy bit line region, obtaining a second electrode groove and a bit line groove, respectively, and forming the second electrode and the bit line connected to the second electrode in the second electrode groove and the bit line groove, respectively.

In an exemplary embodiment of the present disclosure, two ends of the dummy electrode region are respectively connected to two adjacent dummy bit line regions, and each dummy electrode region is connected to two dummy channel and gate regions; the memory cell further includes a capacitor, which includes a third electrode and a fourth electrode.

etching to removing the patterned second insulation layer of the first electrode region, obtaining the first electrode groove, and forming the first electrode in the first electrode groove, and the forming process of the capacitor may include:
filling a stacked structure formed by the patterned first insulation layer and the patterned second insulation layer by using the first insulation layer;
etching the stacked structure along a direction towards the substrate, forming a first groove in the first electrode region extending along the second direction and penetrating through each patterned second insulation layer, wherein the first groove separates the first electrode region into two portions, and the first groove exposes end surfaces of separated first electrode regions on both sides;
laterally etching the patterned second insulation layer on both sides of the first groove, to remove the patterned second insulation layer of the first electrode region, and obtaining first electrode grooves on both sides of the first groove;
depositing a first conductive layer in the first electrode groove;
etching the first insulation layer on both sides of the first groove to expose a side surface, with a set depth, of the first conductive layer; wherein an exposed region of the first conductive layer is a third electrode of the capacitor, and an unexposed region is the first electrode of the transistor; and
sequentially forming a dielectric layer and a fourth electrode of the capacitor on a surface of the third electrode.

In an exemplary embodiment of the present disclosure, etching to remove the patterned second insulation layers of the second electrode region and the dummy bit line region, obtaining the second electrode groove and the bit line groove, respectively, and forming the second electrode and the bit line connected to the second electrode in the second electrode groove and the bit line groove, respectively, may include:
etching the patterned first insulation layer and second insulation layer distributed in a stacked mode along a direction towards the substrate, forming an initial bit line groove in the dummy bit line region extending along the second direction and penetrating through each patterned second insulation layer, laterally etching the patterned second insulation layers on both sides of the initial bit line groove to remove the patterned second insulation layers of the second electrode region and the dummy bit line region, wherein a portion of a sidewall of the initial bit line groove extends into the patterned second insulation layer to obtain a bit line groove located in the dummy bit line region and a second electrode groove located in the second electrode region;
depositing a second conductive layer in the bit line groove and the second electrode groove, and forming a second electrode in the second conductive layer located in the second electrode groove; and
etching the second conductive layer located in the bit line groove along a direction towards the substrate, forming a second groove extending along the second direction and penetrating through each layer bit line groove, wherein the second groove separates the second conductive layer in the bit line groove into two bit lines, and each bit line is connected with a separated column of second electrodes along the second direction; and depositing the first insulation layer in the second groove.

In an exemplary embodiment of the present disclosure, forming the hollow annular semiconductor layer between the first electrode and the second electrode, and the gate electrode with one end surface extending into the semiconductor layer, and after the gate electrode is formed, forming the word line connected to the other end surfaces of the plurality of the gate electrodes, and making the extension direction of the word line be intersected with the extension direction of the gate electrode, may include:
etching a patterned first insulation layer and a patterned second insulation layer on a side of the dummy channel and gate region away from the dummy electrode region, forming a word line groove penetrating through each patterned second insulation layer on the side of the dummy channel and gate region away from the dummy electrode region, wherein the word line groove exposes an end surface of the patterned second insulation layer;
etching the patterned second insulation layer in the word line groove to remove a patterned second insulation layer in the whole dummy channel and gate region, and obtaining a channel groove located in the dummy channel and gate region and connected with one end of the dummy electrode region, and a gate electrode groove located between the channel groove and the word line groove;
sequentially forming a semiconductor layer and a third insulation layer on inner walls of the word line groove, the gate electrode groove and the channel groove, and filling a third conductive layer in remaining spaces of the word line groove, the gate electrode groove and the channel groove; and
etching to remove a third conductive layer and a third insulation layer in the word line groove, etching to remove a semiconductor layer in the word line groove and the gate electrode groove, and depositing a third insulation layer on an inner wall of the gate electrode groove, and depositing a third conductive layer in the word line groove; wherein the semiconductor layer retained in the channel groove serves as the semiconductor layer of the transistor, the third conductive layer located in the gate electrode groove and the channel groove serves as the gate electrode of the transistor, the third conductive layer located in the word line groove serves as the word line, and the third insulation layer located in the channel groove and the gate electrode groove forms a gate insulation layer that insulates the semiconductor layer from the gate electrode and the word line.

An embodiment of the present disclosure also provides an electronic device including the transistor or the 3D stacked semiconductor device as provided above in embodiments of the present disclosure.

Other features and advantages of the present disclosure will be set forth in the following specification, and moreover, partially become clearer from the specification, or are understood by implementing the present disclosure. The objectives and advantages of the present disclosure may be achieved through structures particularly pointed out in the specification and the drawings.

Other aspects may be understood upon reading and understanding the drawings and detailed description.

### BRIEF DESCRIPTION OF DRAWINGS

The accompanying drawings are used for providing understanding of technical solutions of the present disclosure, and form a part of the specification. They are used for explaining the technical solutions of the present disclosure together with the embodiments of the present disclosure, but do not form a limitation on the technical solutions of the present disclosure.

FIG. 1A is a schematic diagram of a structure of a transistor according to an exemplary embodiment of the present disclosure.

FIG. 1B is a cross-sectional view of the transistor shown in FIG. 1A.

FIG. 2A is a schematic diagram of a structure of a 3D stacked semiconductor device according to an exemplary embodiment of the present disclosure.

FIG. 2B is a cross-sectional view of the semiconductor device shown in FIG. 2A on a C1 plane parallel to a substrate.

FIG. 2C is a cross-sectional view of the semiconductor device shown in FIG. 2A on a C2 plane perpendicular to a substrate.

FIG. 2D is a cross-sectional view of the semiconductor device shown in FIG. 2A on a C3 plane perpendicular to a substrate.

FIG. 3A is a schematic diagram of a partial structure of another 3D stacked semiconductor device according to an exemplary embodiment of the present disclosure.

FIG. 3B is a perspective view of the semiconductor device shown in FIG. 3A in a top view direction.

FIG. 4 is a schematic diagram of a structure of another 3D stacked semiconductor device according to an exemplary embodiment of the present disclosure.

FIG. 5 is a process flowchart of a method for manufacturing a 3D stacked semiconductor device according to an exemplary embodiment of the present disclosure.

FIG. 6A is a schematic diagram of a three-dimensional structure after a stacked structure of a 3D stacked semiconductor device is formed by using a manufacturing method according to an exemplary embodiment of the present disclosure.

FIG. 6B is a cross-sectional view of the structure shown in FIG. 6A on a C1 plane parallel to the substrate.

FIG. 6C is a cross-sectional view of the structure shown in FIG. 6A on a C2 plane perpendicular to the substrate.

FIG. 6D is a cross-sectional view of the structure shown in FIG. 6A on a C3 plane perpendicular to the substrate.

FIG. 7A is a cross-sectional view after a patterned second insulation layer of a 3D stacked semiconductor device is formed by using a manufacturing method on a C1 plane parallel to the substrate according to an exemplary embodiment of the present disclosure.

FIG. 7B is a cross-sectional view of the structure shown in FIG. 7A in a C2 plane perpendicular to the substrate.

FIG. 8A is a cross-sectional view after a first electrode groove of a 3D stacked semiconductor device is formed by using a manufacturing method on a C1 plane parallel to the substrate according to an exemplary embodiment of the present disclosure.

FIG. 8B is a cross-sectional view of the structure shown in FIG. 8A on a C2 plane perpendicular to the substrate.

FIG. 8C is a cross-sectional view of the structure shown in FIG. 8A on a C3 plane perpendicular to the substrate.

FIG. 9A is a cross-sectional view after a first conductive layer of a 3D stacked semiconductor device is formed by using a manufacturing method on a C1 plane parallel to the substrate according to an exemplary embodiment of the present disclosure.

FIG. 9B is a cross-sectional view of the structure shown in FIG. 9A on a C2 plane perpendicular to the substrate.

FIG. 9C is a cross-sectional view of the structure shown in FIG. 9A on a C3 plane perpendicular to the substrate.

FIG. 10A is a cross-sectional view after a third electrode of a 3D stacked semiconductor device is formed by using a manufacturing method on a C1 plane parallel to the substrate according to an exemplary embodiment of the present disclosure.

FIG. 10B is a cross-sectional view of the structure shown in FIG. 10A on a C2 plane perpendicular to the substrate.

FIG. 10C is a cross-sectional view of the structure shown in FIG. 10A on a C3 plane perpendicular to the substrate.

FIG. 11A is a cross-sectional view after a forth electrode of a 3D stacked semiconductor device is formed by using a manufacturing method on a C1 plane parallel to the substrate according to an exemplary embodiment of the present disclosure.

FIG. 11B is a cross-sectional view of the structure shown in FIG. 11A on a C2 plane perpendicular to the substrate.

FIG. 11C is a cross-sectional view of the structure shown in FIG. 11A on a C3 plane perpendicular to the substrate.

FIG. 12A is a cross-sectional view after a second electrode groove of a 3D stacked semiconductor device is formed by using a manufacturing method on a C1 plane parallel to the substrate according to an exemplary embodiment of the present disclosure.

FIG. 12B is a cross-sectional view of the structure shown in FIG. 12A on a C2 plane perpendicular to the substrate.

FIG. 12C is a cross-sectional view of the structure shown in FIG. 12A on a C3 plane perpendicular to the substrate.

FIG. 13A is a cross-sectional view after a bit line of a 3D stacked semiconductor device is formed by using a manufacturing method on a C1 plane parallel to the substrate according to an exemplary embodiment of the present disclosure.

FIG. 13B is a cross-sectional view of the structure shown in FIG. 13A on a C2 plane perpendicular to the substrate.

FIG. 13C is a cross-sectional view of the structure shown in FIG. 13A on a C3 plane perpendicular to the substrate.

FIG. 14A is a cross-sectional view after a channel groove of a 3D stacked semiconductor device is formed by using a manufacturing method on a C1 plane parallel to the substrate according to an exemplary embodiment of the present disclosure.

FIG. 14B is a cross-sectional view of the structure shown in FIG. 14A on a C2 plane perpendicular to the substrate.

FIG. 14C is a cross-sectional view of the structure shown in FIG. 14A on a C3 plane perpendicular to the substrate.

FIG. 15A is a cross-sectional view after a semiconductor layer of a 3D stacked semiconductor device is formed by using a manufacturing method on a C1 plane parallel to the substrate according to an exemplary embodiment of the present disclosure.

FIG. 15B is a cross-sectional view of the structure shown in FIG. 15A on a C2 plane perpendicular to the substrate.

FIG. 16A is a cross-sectional view after a semiconductor layer of a 3D stacked semiconductor device in a word line groove is removed by using a manufacturing method on a C1 plane parallel to the substrate according to an exemplary embodiment of the present disclosure.

FIG. 16B is a cross-sectional view of the structure shown in FIG. 16A on a C2 plane perpendicular to the substrate.

Meanings of reference signs in the accompanying drawings are as follows:
1—Substrate; 2—Hard mask; 10—First electrode; 20—Second electrode; 30—Semiconductor layer; 31—Electrode contact region; 32—First channel region; 40—Gate electrode; 50—Gate insulation layer; 60—Memory cell; 70—Transistor; 80—Word line; 81—Word line branch; 90—Bit line; 100—Capacitor; 101—Third electrode; 102—Fourth electrode; 103—Dielectric layer; 11—First insulation layer; 12—Second insulation layer; 13—Dummy bit line region; 14—Dummy electrode region; 141—First electrode region; 142—Second electrode region; 15—Dummy channel and gate region; 16—First conductive layer; 18—Third insulation layer; 19—Third conductive layer; 21—First groove; 22—First electrode groove; 23—Bit line groove; 24—Second electrode groove; 25—Second groove; 26—Word line groove; 27—Channel groove; 28—Gate electrode groove.

### DETAILED DESCRIPTION

To make the objectives, technical solutions, and advantages of the present disclosure clearer, the embodiments of the present disclosure will be described in detail below in combination with the accompany drawings. It should be noted that the embodiments of the present disclosure and the features of the embodiments may be arbitrarily combined with each other if there is no conflict.

An implementation of the present disclosure is not necessarily limited to dimensions shown in the drawings, and the shapes and sizes of the components in the drawings do not reflect actual scales. Further, the drawings schematically illustrate ideal examples, but embodiments of the present disclosure are not limited to shapes or values shown in the drawings.

Ordinal numerals such as “first” and “second” in the present disclosure are provided to avoid confusion of constituent elements, but do not indicate any order, quantity or importance.

In the present disclosure, for convenience, words or expressions indicating orientation or positional relationship such as “middle”, “upper”, “lower”, “front”, “rear”, “vertical”, “horizontal”, “top”, “bottom”, “inner” and “outer” are employed to explain the positional relationship of the constituent elements with reference to the accompanying drawings, they are employed for ease of description of the specification and simplification of the description only, but do not indicate or imply that the referred device or element must have a particular orientation and be constructed and operate in a particular orientation, and therefore cannot be construed as limitations to the present disclosure. The positional relationship of the constituent elements is appropriately changed according to the direction in which each constituent element is described. Therefore, the present disclose is not limited to the words or expressions described in the present disclosure, and replacement may be appropriately made according to the situation.

In the present disclosure, the terms “mount”, “couple” and “connect” should be understood broadly, unless otherwise expressly specified and defined. For example, a connection may be a fixed connection, a detachable connection, or an integral connection; it may be a mechanical connection or an electrical connection; it may be a direct connection, indirect connection through a middleware, or internal communication between two elements. For those of ordinary skills in the art, the specific meaning of the above terms in the present disclosure may be understood according to actual situations.

In the present disclosure, a transistor refers to an element including at least three terminals, i.e., a gate electrode, a drain electrode, and a source electrode. A transistor has a channel region between a drain electrode (drain electrode terminal, drain region, or drain) and a source electrode (source electrode terminal, source region, or source), and a current may flow through the drain electrode, the channel region, and the source electrode. In the present disclosure, the channel region refers to the region through which the current mainly flows.

In the present disclosure, the first electrode may be a drain electrode and the second electrode may be a source electrode, or the first electrode may be a source electrode and the second electrode may be a drain electrode. In cases that transistors with opposite polarities are used, or a current direction changes during work of a circuit, or the like, functions of the “source electrode” and the “drain electrode” may sometimes be exchanged. Therefore, in the present disclosure, the “source electrode” and the “drain electrode” may be interchangeable with each other unless specifically stated.

In the present disclosure, “electrical connection” or “connection” includes a case where constituent elements are connected together through an element with a certain electrical effect, such as electrical signal connection (coupling connection, such as coupled to), or physical direct connection. There is no special restriction on “elements with certain electrical effects” as long as they can transmit and receive electrical signals between connected constituent elements. Examples of “elements having certain electrical effects” include not only electrodes and wiring, but also switching elements (such as transistors), resistors, inductors, capacitors, and other elements having various functions, etc.

In the present disclosure, “parallel” refers to approximately parallel or almost parallel, for example, a state in which the angle formed by two straight lines is −10 degrees or more and 10 degrees or less, and therefore also includes a state in which the angle is −5 degrees or more and 5 degrees or more. In addition, “perpendicular” refers to “approximately perpendicular”, for example, a state in which the angle formed by two straight lines is 80 degrees or more and 100 degrees or less, and therefore also includes a state in which the angle is 85 degrees or more and 95 degrees or less.

In some embodiments of the present disclosure, the “film” and “layer” may be interchangeable with each other. For example, “conductive layer” may sometimes be replaced by “conductive film”. Similarly, “insulation film” may sometimes be replaced by “insulation layer”.

In this disclosure, “A and B are arranged on the same layer” means that A and B are distributed on the same horizontal plane, or although they are not on the same horizontal plane, they are all in different regions on the same supporting plane. In one embodiment, A and B are formed simultaneously through a same patterning process on a same film layer.

The “A and B are of an integral structure” in embodiments of the present disclosure may mean that there is no obvious boundary interface, such as obvious faultage or gaps, viewed from the microstructure. Generally, the connected film layers formed by patterning on one film layer are of an integral structure. For example, A and B use the same material to form a film layer and form a structure with connection relationship simultaneously through the same patterning process, or B is directly grown on A epitaxially, and both the materials may not be completely the same.

The substrate in embodiments of the present disclosure may be a supporting structure, such as a silicon substrate, or a supporting structure on which other films or functional layers or circuits have been distributed on a silicon substrate, and the device which the inventive structure of the embodiment of the present disclosure relates to is arranged on an upper major surface of the support structure.

An embodiment of the present disclosure provides a transistor including: a first electrode and a second electrode arranged on a substrate, a semiconductor material or a semiconductor layer arranged between the first electrode and the second electrode, and a gate electrode insulated from the semiconductor material and the semiconductor layer. The first electrode and the second electrode are separated in a first direction parallel to the substrate. The gate electrode includes a side wall and two end surfaces, one end surface is configured to be connected with a word line; at least a portion of the side wall of the gate electrode is surrounded by the semiconductor layer; and an extension direction of the gate electrode intersects with an extension direction of the word line.

In various embodiments of the present disclosure, the first direction parallel to the substrate may be understood as lateral. In various embodiments of the present disclosure, the distribution at intervals may be understood as a separated distribution.

In some embodiments, an extension direction of the gate electrode intersects with (e.g., perpendicular to) the first direction. The gate electrode may extend in a plane parallel to the substrate, or in a plane perpendicular to the substrate. The gate electrode has two end surfaces in the extension direction, and a region between the two end surfaces is a side wall of the gate electrode. The first electrode and the second electrode are adjacent to two opposite sidewalls of the gate electrode.

At least a portion of the side walls of the gate electrode are surrounded by the semiconductor layer, which may be understood that the semiconductor layer surrounds various side walls of the gate electrode, forming an annular semiconductor layer, or the semiconductor layer is distributed on a portion of the side walls of the gate electrode, forming semiconductor layers separated from each other on the side walls.

The annular semiconductor layer may be understood as the semiconductor layer surrounding various regions or a portion of regions of various sidewalls of the gate electrode. For example, a width of the semiconductor layer after surrounding is consistent with a length of the gate electrode, and the surrounding film layer is a continuous film layer. For example, the width of the semiconductor layer after surrounding is smaller than the length of the gate electrode, and the surrounding film layer is a continuous film layer. The width is a length in a direction in which the gate electrode extends.

In an exemplary embodiment of the present disclosure, the gate electrode may extend in a second direction parallel to the substrate, the first direction intersects with the second direction, for example, an angle of the intersection is about or equal to 90 degrees; and the word line may extend along the first direction or a direction perpendicular to the substrate.

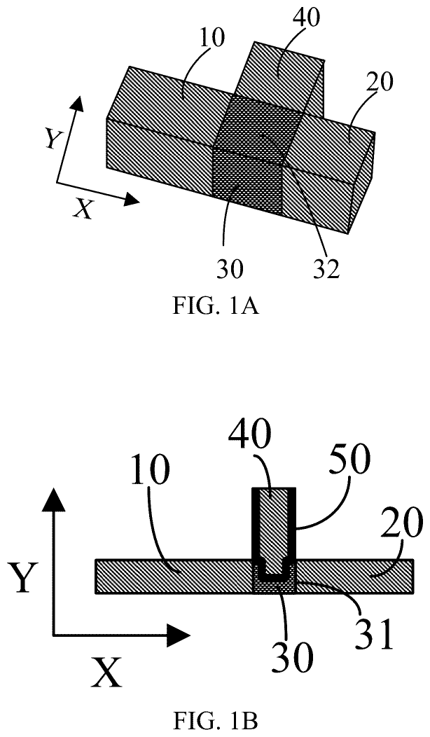

FIG. 1A is a schematic diagram of a structure of a transistor according to an exemplary embodiment of the present disclosure; and FIG. 1B is a cross-sectional view of the transistor shown in FIG. 1A.

As shown in FIG. 1A and FIG. 1B, the transistor includes a first electrode 10, a second electrode 20, a semiconductor layer 30, and a gate electrode 40 extending into the semiconductor layer 30.

In some embodiments, the transistor is arranged on the substrate, and the first electrode 10 and the second electrode 20 are separated in a first direction parallel to the substrate, and the first and second electrodes 10 and 20 may further extend along the first direction.

The semiconductor layer 30 is arranged between the first electrode 10 and the second electrode 20; and the semiconductor layer 30 may be understood as a semiconductor material where its shape configuration is not emphasized and only its function is emphasized.

The gate electrode 40 is insulated from the semiconductor layer 30, and extends along a second direction parallel to the substrate. The gate electrode 40 includes a sidewall extending along the second direction, and two end surfaces, wherein one end surface may be electrically connected to a word line (the word line and its extension direction are embodied in a subsequent 3D stacked semiconductor device including the transistor), and at least a portion of the sidewall of the gate electrode 40 is surrounded by the semiconductor layer 30; and the first direction intersects with the second direction.

The gate electrode of the transistor according to an embodiment of the present disclosure extends in a direction different from an arrangement direction of the source electrode and the drain electrode, so that the semiconductor layer may surround the sidewall, or the sidewall and the other end surface of the gate electrode, effectively increasing the channel region, thus can improving an on-state current of the semiconductor device.

The arrangement direction of the source electrode and the drain electrode is the first direction. The extension direction of the source electrode and the drain electrode are not limited therein.

The first direction may be an X direction as shown in FIG. 1A, the second direction may be a Y direction as shown in FIG. 1A, and of course, may be a Z direction perpendicular to the X direction and the Y direction. The first direction and the second direction may be perpendicular to each other.

Herein, the surrounding the gate electrode by the semiconductor layer may be understood as a partial surrounding the gate electrode or a full surrounding the gate electrode. In some embodiments, the surrounding may be a full surrounding i.e. a surrounding along each sidewall of the gate electrode. At this point, the number of the surrounded side walls is emphasized, and a size of the surrounded region is not limited. At least each sidewall of the gate electrode 40 is surrounded by a semiconductor layer 30, and a cross section of the semiconductor layer 30 after surrounding is an annulus which is closed or has an opening. The cross section is taken along a direction perpendicular to the substrate and parallel to an extension direction of the first direction. As shown in FIG. 1B, the entire sidewall and one end surface of the gate electrode 40 are surrounded by the semiconductor layer 30, and this surrounding is also a full surrounding. In some embodiments, the surrounding may be a partial surrounding, i.e. a portion of the sidewall of the gate electrode 40 is surrounded by the semiconductor layer 30. If three side surfaces are continuously surrounded, the cross section after surrounding is U-shaped, and if two opposite side surfaces are surrounded, the cross section is two separated lines. The cross section is a surface taken along an extension direction perpendicular to the gate electrode.

In an exemplary embodiment of the present disclosure, the other end face of the gate electrode 40 may be surrounded by the semiconductor layer 30. It may be understood that the semiconductor layer not only surrounds all or a portion of the side wall of the gate electrode, but also surrounds one end surface of the gate electrode, and this end surface is arranged opposite to the end surface which is connected with the word line.

In some embodiments, the semiconductor layer surrounding the gate electrode is a continuous film layer. The semiconductor layers on the end surface and on the sidewall are continuously distributed.

The semiconductor layer surrounding the gate electrode may be understood to be adjacent to the sidewall and/or end surface of the gate electrode and separated by a gate insulation layer.

The semiconductor layer surrounding the gate electrode may be a hollow tubular structure, a cup-shaped structure, or a hollow structure after two opposite side walls is connected with an end surface.

In an exemplary embodiment of the present disclosure, the semiconductor layer 30 includes at least two electrode contact regions and a channel region, wherein the electrode contact regions are in contact with a first electrode and a second electrode of the transistor, respectively, and the channel region is located between the first electrode and the second electrode, and is simultaneously connected to the first electrode and second electrode. As shown in FIG. 1A and FIG. 1B, the semiconductor layer 30 may be a hollow tubular structure, and the tubular structure has a side surface, a bottom surface and an opening. The side surface includes two separated opposite electrode contact regions 31, which are in contact with the first electrode 10 and the second electrode 20, respectively. A region of the side surface and the bottom surface of the tubular structure located between the first electrode 10 and the second electrode 20 and a region of the side surface and the bottom surface of the tubular structure located between the two electrode contact regions 31 are a channel region of the transistor; for example, the channel region may include a first channel region and a second channel region according to different distribution positions, wherein the first channel region is distributed on the side surface, and the second channel region is distributed on the bottom surface. The side surface of the tubular structure includes two separated first channel regions 32 in addition to the two electrode contact regions 31, and the second channel region is located on the bottom surface of the tubular structure.

In an exemplary embodiment of the present disclosure, an outer profile of the cross section of the tubular structure of the semiconductor layer may be in a shape of a square, a circle, a rectangle and the like. The cross section is a surface taken along a direction perpendicular to an extension direction of the side wall of the tubular structure.

In an exemplary embodiment of the present disclosure, as shown in FIG. 1A and FIG. 1B, the semiconductor layer 30 is of a full-surrounding type, and may have four side surfaces which are two pair of opposite side surfaces, wherein two opposite side surfaces are the electrode contact regions 31, and the other two opposite sides are two first channel regions 32.

In an exemplary embodiment of the present disclosure, as shown in FIG. 1B, the gate electrode 40 may extend into an accommodation space formed by an inner side wall of the semiconductor layer 30 through the opening of the tubular structure.

In an exemplary embodiment of the present disclosure, a material of the semiconductor layer may be a material such as silicon or polysilicon with a band gap less than 1.65 eV, or a material with a wide band gap, such as a metal oxide material with a band gap greater than 1.65 eV.

For example, the material of the metal oxide semiconductor layer or channel may include a metal oxide of at least one of the following metals: indium, gallium, zinc, tin, tungsten, magnesium, zirconium, aluminum, hafnium and the like. Of course, compounds containing other elements, such as N, Si and other elements, are not excluded from the metal oxide; and it is not excluded that the metal oxide contains a small amount of other doping elements.

In some embodiments, the material of the metal oxide semiconductor layer or channel may include one or more of the followings: indium gallium zinc oxide (InGaZnO), indium zinc oxide (InZnO), indium gallium oxide (InGaO), indium tin oxide (InGaSnO), indium gallium tin oxide (InGaZnSnO), indium oxide (InO), tin oxide (SnO), zinc tin oxide (ZnSnO, ZTO), indium aluminum zinc gold oxide (InAlZnO), zinc oxide (ZnO), indium gallium silicon oxide (InGaSiO), indium tungsten oxide (InWO, IWO), titanium oxide (TiO), zinc nitride (ZnON), magnesium zinc oxide (MgZnO), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), aluminum zinc tin oxide (AlZnSnO), gallium zinc tin oxide (GaZnSnO), zirconium zinc tin oxide (ZrZnSnO) and the like, the specific application may be adjusted according to the actual situations as long as it can ensure that the drain current of the transistor can meet the requirements.

These materials have a wide band gap and low leakage current. For example, when the metal oxide material is IGZO, the leakage current of the transistor is less than or equal to 10⁻¹⁵ A, thereby improving the working performance of the dynamic memory.

The material of the metal oxide semiconductor layer or channel only emphasizes the element type of the material, and does not emphasize the atomic proportion in the material and the film quality of the material.

In an exemplary embodiment of the present disclosure, an electrode material of the gate electrode may be any one or more of the following different types of materials.

For example, it is a metal containing tungsten, aluminum, titanium, copper, nickel, platinum, ruthenium, molybdenum, gold, iridium, rhodium, tantalum, cobalt and the like; or it may be a metal alloy containing these metals mentioned above.

It may also be metal oxide, metal nitride, metal silicide and metal carbide, which is, for example, a metal oxide material with high conductivity such as indium tin oxide ITO, indium zinc oxide IZO and indium oxide InO; for example, it is a metal nitride material such as titanium nitride (TiN), tantalum nitride (TaN), tungsten nitride (WN) and titanium aluminum nitride (TiAlN).

Of course, it may also be a polysilicon material; or it may also be a semiconductor material doped with a conductive material, such as silicon doped with conductive material, germanium doped with conductive material, silicon germanium doped with conductive material, etc., or it may be another material that embodies conductivity.

In an exemplary embodiment of the present disclosure, as shown in FIG. 1B, a gate insulation layer 50 which plays an insulation role may be provided between the gate electrode 40 and the semiconductor layer 30.

In an exemplary embodiment of the present disclosure, a material of the gate insulation layer may contain one or more layers of Low-K and/or High-K dielectric material, or contain two or more regions of different dielectric constants K. The characteristics of the gate insulation layer of the present application will be illustrated exemplarily below.

An example of Low-K material is silicon oxide.

An example of a High-K material is a dielectric material with a dielectric constant K≥of 3.9. In some embodiments, one or more oxides of hafnium, aluminum, lanthanum, zirconium and the like may be included. Exemplarily, for example, at least one of the followings may be included but is not limited to hafnium oxide (HfO₂), alumina oxide (Al₂O₃), hafnium aluminum oxide (HfAlO), hafnium lanthanum oxide (HfLaO), zirconium oxide (ZrO₂) which are High K materials.

In an exemplary embodiment of the present disclosure, as shown in FIG. 1A and FIG. 1B, the first electrode 10 and the second electrode 20 may be located in a same horizontal plane parallel to the substrate, and may be conductive layers or conductive structures of the same material or different materials, and in some embodiments, the first electrode 10 and the second electrode 20 may be formed separately by patterning on a same conductive film layer, which may have characteristics such as the same material and thickness.

In an exemplary embodiment of the present disclosure, as shown in FIG. 1A and FIG. 1B, the outer surface of the channel region of the semiconductor layer 30 and the outer surface of the adjacent first electrode 10 and/or second electrode 20 may be located in the same horizontal plane. That is, the outer surface of the channel region of the semiconductor layer 30 may be in the same horizontal plane as the outer surface of the adjacent first electrode 10; or the outer surface of the channel region of the semiconductor layer 30 may be in the same horizontal plane as the outer surface of the adjacent second electrode 20; and for example, the outer surface of the channel region of the semiconductor layer 30 may be in the same horizontal plane as the outer surfaces of the adjacent first electrode 10 and second electrode 20.

For example, two first channel regions 32 of the semiconductor layer 30 are located on two side surfaces of the tubular structure, and are parallel to the substrate, and the two side surfaces are an upper surface and a lower surface of the tubular structure, respectively, and are coplanar with upper surfaces and lower surfaces of the first electrode and the second electrode, respectively. The second channel region is located on a bottom surface of the tubular structure, and the bottom surface is coplanar with a side surface between the upper surfaces and the lower surfaces of the first electrode and the second electrode.

In an exemplary embodiment of the present disclosure, as shown in FIGS. 1A and 1B, an orthographic projection of the first electrode 10 on the substrate is not overlapped with an orthographic projection of the second electrode 20 on the substrate. The upper surfaces of the first electrode and the second electrode are coplanar, the lower surfaces of the first electrode and the second electrode are coplanar, and the side surfaces of the first electrode and the second electrode are coplanar, wherein the upper surfaces and the lower surfaces are relative to the substrate. Being coplanar may be understood as being in the same horizontal plane.

An embodiment of the present disclosure also provides a 3D stacked semiconductor device, including a word line and a plurality of memory cells; and the plurality of memory cells contain a plurality of above transistors.

Specifically, the plurality of memory cells are distributed in different layers, stacked periodically along a direction perpendicular to the substrate. Each layer includes a plurality of columns of memory cells in a two-dimensional plane, and each of the memory cells includes the transistor in the above embodiments.

Specifically, the transistor includes a first electrode, a second electrode, a semiconductor layer arranged between the first electrode and the second electrode, and a gate electrode. The first electrode and the second electrode are separated in a first direction parallel to the substrate. the gate electrode includes a side wall and two end surfaces, wherein one end surface is configured to be connected with the word line, and the other end surface extends into a hollow annular semiconductor layer; and an extension direction of the gate electrode intersects with an extension direction of the word line.

In an exemplary embodiment of the 3D stacked semiconductor device of the present disclosure, the gate electrode may extend along a second direction parallel to the substrate, and the first direction intersects with the second direction.

It should be understood that the length in the extension direction of the gate electrode is not limited to be larger than the width of the cross section of the gate electrode, but only for convenience of expression, it is to limit that the gate electrode extends along a direction perpendicular to the distribution of the first electrode and the second electrode, the end surface extended from the gate electrode may be connected to the word line, and the other end may extend into the semiconductor layer with the hollow structure.

The gate electrode may extend in a plane parallel to the substrate or extend along a direction perpendicular to the substrate.

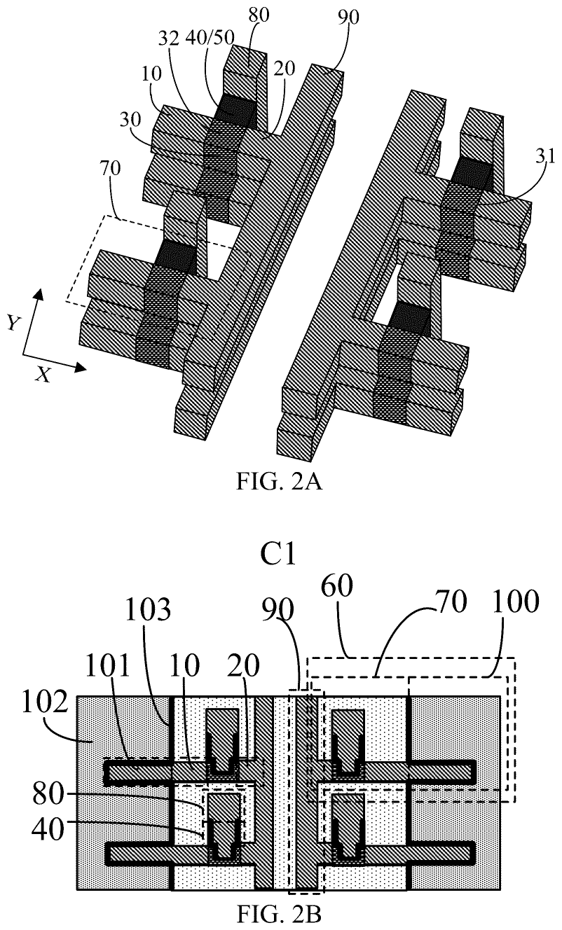

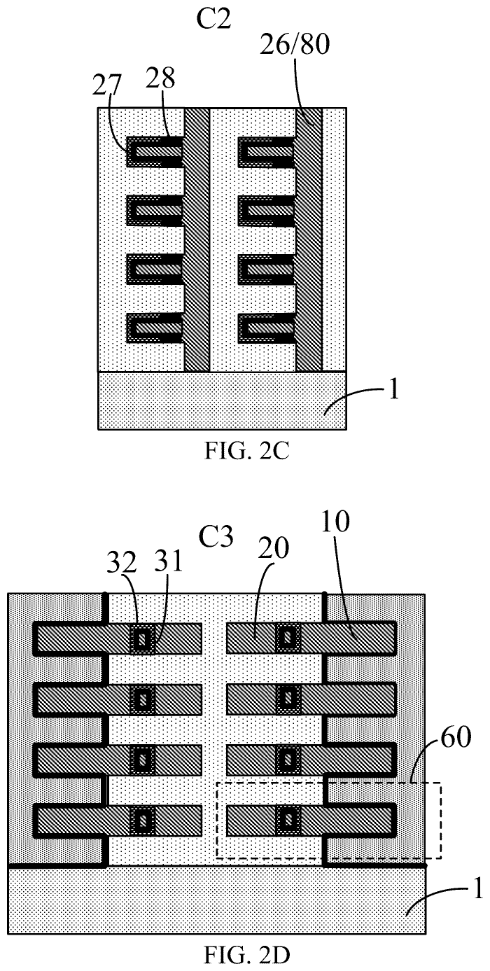

FIG. 2A is a schematic diagram of a structure of a 3D stacked semiconductor device according to an exemplary embodiment of the present disclosure; FIG. 2B is a cross-sectional view of the semiconductor device shown in FIG. 2A on a C1 plane parallel to a substrate; FIG. 2C is a cross-sectional view of the semiconductor device shown in FIG. 2A on a C2 plane perpendicular to a substrate, wherein the C2 plane extends along a second direction and passes through the semiconductor layer of the transistor; FIG. 2D is a cross-sectional view of the semiconductor device shown in FIG. 2A on a C3 plane perpendicular to a substrate, wherein the C3 plane extends along a first direction and passes through the semiconductor layer of the transistor.

As shown in FIGS. 2A, 2B, 2C, and 2D, the semiconductor device includes: a plurality of memory cells 60, distributed in different layers, stacked periodically along a direction perpendicular to a plane composed of X and Y. Each layer includes a plurality of columns of memory cells 60, and a memory cell 60 includes a transistor 70.

The transistor 70 includes a first electrode 10, a second electrode 20, a semiconductor layer 30 between the first electrode 10 and the second electrode 20, and a gate electrode 40.

The first electrode 10 and second electrode 20 may be separated along a first direction parallel to the substrate; and the first electrode 10 and the second electrode 20 may further extend along the first direction.

The semiconductor layer 30 may be a structure having a hollow cross section which is an annular.

The gate electrode 40 extends along a second direction parallel to the plane composed of X and Y, and the gate electrode 40 includes a sidewall and two end surfaces extending along the second direction, wherein one end surface may be connected to a word line, and the other end surface extends into the hollow semiconductor layer 30; at least a portion of the sidewall of the gate electrode 40 may be surrounded by the semiconductor layer 30; and the first direction intersects with the second direction.

The gate electrode of the 3D stacked semiconductor device according to an embodiment of the present disclosure extends in a different extension direction from an extension direction of the source electrode and the drain electrode, so that more regions in the semiconductor layer may be used for transporting carriers, thereby increasing the on-state current of the semiconductor device.

In an exemplary embodiment of the present disclosure, as shown in FIG. 2B and FIG. 2C, an end surface of the gate electrode 40 extending into the semiconductor layer 30 may be surrounded by the semiconductor layer 30.

In an exemplary embodiment of the present disclosure, the gate electrode extends only along a direction parallel to the substrate, for example, extends only along the second direction.

In an exemplary embodiment of the present disclosure, the first direction may be the X direction as shown in FIG. 2A, and the second direction may be the Y direction as shown in FIG. 2A. The first direction and the second direction may be perpendicular to each other.

The above memory cell may be a memory cell containing a transistor, the transistor may be an access transistor, and the memory cell may also include other elements, such as a capacitor in a 1T1C memory cell, or include a read transistor and a memory node in a 2T0C memory cell.

In an exemplary embodiment of the present disclosure, the semiconductor layer 30 includes an electrode contact region and a channel region, wherein the electrode contact region is in contact with a first electrode and a second electrode of the transistor, respectively, and the channel region is located between the first electrode and the second electrode, and is simultaneously connected to the first electrode and second electrode. The semiconductor layer 30 may be a hollow tubular structure, which has a side surface, a bottom surface and an opening. The side surface includes two separated electrode contact regions 31, which are in contact with the first electrode 10 and the second electrode 20, respectively, a region of the side surface and the bottom surface of the tubular structure located between the first electrode 10 and the second electrode 20 is a channel region of the transistor; and for example, the channel region may include a first channel region and a second channel region, the side surface of the tubular structure also includes two separated first channel regions 32 in addition to the two electrode contact regions 31, and the second channel region is located on the bottom surface of the tubular structure.

In an exemplary embodiment of the present disclosure, as shown in FIG. 2A and FIG. 2B, the semiconductor layer 30 may have four side surfaces which are two pair of opposite side surfaces, wherein two opposite side surfaces are the electrode contact regions 31, and the other two opposite side surfaces are the first channel regions 32. That is, the semiconductor layer has five surfaces, three of which may be conductive, which may effectively increase the on-state current of the semiconductor device.

In an exemplary embodiment of the present disclosure, as shown in FIG. 2B and FIG. 2C, the gate electrode 40 may extend into the interior of the tubular structure through the opening of the tubular structure.

In an exemplary embodiment of the present disclosure, as shown in FIG. 2B and FIG. 2C, the gate electrode 40 may extend to the bottom surface of the tubular structure through the opening of the tubular structure.

In an exemplary embodiment of the present disclosure, as shown in FIG. 2B, a gate insulation layer 50 which plays an insulation role may be provided between the gate electrode 40 and the semiconductor layer 30.

In an exemplary embodiment of the present disclosure, the channel between the first electrode and the second electrode may be a horizontal channel, and the transistor is a horizontal or lateral transistor.

Horizontal channel means that a transport direction of carriers in the channel is in a plane parallel to the substrate, but it is not limited that the transport direction of the carriers must be one direction. In practical applications, the transport direction of the carriers extends in one direction as a whole, but locally, it is related to a shape of the semiconductor layer. In other words, the horizontal channel does not mean that it must extend along one direction in the horizontal plane, but may extend along different directions. For example, when the semiconductor layer is annular, the source contact region and the drain contact region on the annular semiconductor layer are a portion of the annulus, and in this case, carriers extend along one direction from the source contact region to the drain contact region as a whole, but may not be in one direction locally. Of course, the transport direction of the carriers in a plane parallel to the substrate is also a macroscopic concept, and is not limited to being absolutely parallel to the substrate. The present disclosure protects the channel between the first electrode and the second electrode as a channel not perpendicular to the substrate.

In an exemplary embodiment of the present disclosure, the semiconductor device may also include a plurality of word lines and a plurality of bit lines, and the word lines and the bit lines are cross-distributed, such as vertically distributed.

The word lines may extend along a direction perpendicular to the substrate, or in a direction parallel to the substrate, and the word lines are perpendicular to or parallel to an extension direction of the gate electrode. In the semiconductor device shown in FIG. 2A, the word lines are perpendicular to the substrate in the extension direction, and the bit lines are located in different layers.

In some exemplary embodiments of the present disclosure, the semiconductor device may also include a plurality of bit lines extending along the second direction; and transistors of a column of memory cells located on a same layer and arranged along the second direction are connected to a same bit line.

In an exemplary embodiment of the present disclosure, as shown in FIGS. 2A, 2B, and 2C, the semiconductor device may also include a plurality of Word Lines (WL) 80 extending along a direction perpendicular to the substrate 1, and a plurality of Bit Lines (BL) 90 extending along the second direction. Gate electrodes 40 of transistors of a column of memory cells located in different layers are connected to the same word line 80; and transistors of a column of memory cells located in the same layer and arranged in the second direction are connected to the same bit line 90.

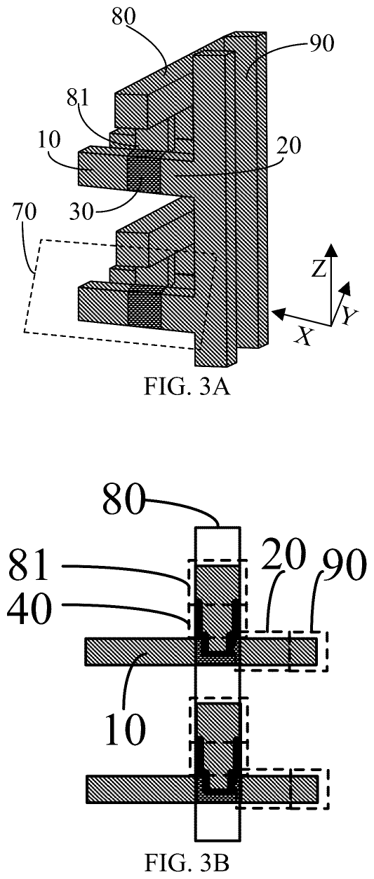

FIG. 3A is a schematic diagram of a partial structure of another 3D stacked semiconductor device according to an exemplary embodiment of the present disclosure; and FIG. 3B is a perspective view of the semiconductor device shown in FIG. 3A in a top view direction. As shown in FIG. 3A and FIG. 3B, in an exemplary embodiment of the present disclosure, the gate electrode 40 may extend along the second direction; the word line 80 may extend along the second direction as a whole, and is connected with the gate electrode 40 through a word line branch 81; and the gate electrodes 40 of the transistors 70 of a column of memory cells located in the same layer and arranged along the second direction are connected to the same word line 80. The semiconductor device may also include a plurality of bit lines 90 extending along a direction perpendicular to the substrate 1 (i.e. the Z direction as shown in FIG. 3A); and the transistors 70 of a column of memory cells located in different layers are connected to the same bit line 90.

In an exemplary embodiment of the present disclosure, as shown in FIG. 2A and FIG. 2B, two adjacent transistors located on the same layer and arranged along the first direction may be connected to different bit lines 90, respectively.

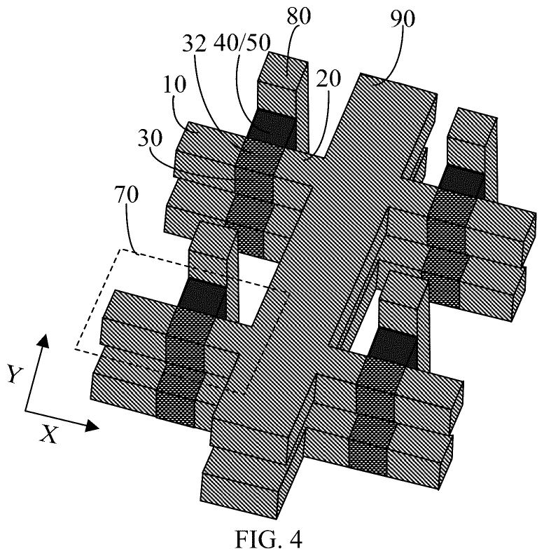

FIG. 4 is a schematic diagram of a structure of another 3D stacked semiconductor device according to an exemplary embodiment of the present disclosure. As shown in FIG. 4, in an exemplary embodiment of the present disclosure, two adjacent transistors located in the same layer and arranged along the first direction may be connected to the same bit line 90, respectively, and in this case, the bit line is a common bit line.

The gate electrode of an embodiment of the present disclosure has an extension direction different from the extension direction of the word line, so that there may be more regions in the semiconductor layer for transporting carriers, i.e. there are more conductive regions, which can thus increase the on-state current of the semiconductor device.

In an exemplary embodiment of the present disclosure, as shown in FIG. 2A and FIG. 4, the bit line 90, and the second electrode 20 of the transistor connected to the bit line 90 may be of an integral structure. The second electrode 20 of the transistor connected to the bit line 90 may be a drain electrode.

In an exemplary embodiment of the present disclosure, as shown in FIG. 2B and FIG. 2C, the gate electrode 40 and the word line 80 connected thereto may be of an integral structure.

In an exemplary embodiment of the present disclosure, the word line may be formed by or include a conductive material, and the conductive material may be, for example, one of a doped semiconductor material, a conductive metal nitride, a metal material, and a metal-semiconductor compound, such as W, or the like; and exemplarily, a material of the gate electrode may include, but is not limited to, at least one of the followings: Indium Tin Oxide (ITO), a composite film layer of TiN and W, Aluminum doped Zinc Oxide (AZO), and Indium Zinc Oxide (IZO).

In an exemplary embodiment of the present disclosure, the bit line may be formed by or include a conductive material, and the conductive material may be, for example, one of a doped semiconductor material, a conductive metal nitride, a metal material, and a metal-semiconductor compound, such as W, or the like; and exemplarily, a material of the gate electrode may include, but is not limited to, at least one of the followings: Indium Tin Oxide (ITO), a composite film layer of TiN and W, Aluminum doped Zinc Oxide (AZO), and Indium Zinc Oxide (IZO).

In an exemplary embodiment of the present disclosure, as shown in FIG. 2B, for an application scenario of the 1T1C, the memory cell 60 may further include a capacitor 100, which includes a third electrode 101, a fourth electrode 102, and a dielectric layer 103 arranged between the third electrode 101 and the fourth electrode 102 for an insulation function, wherein the third electrode 101 is connected to the first electrode 10 of the transistor 70.

In an exemplary embodiment of the present disclosure, as shown in FIG. 2B, the third electrode 101 and the first electrode 10 connected thereto may be located in a same conductive layer parallel to the substrate. For example, the third electrode 101 and the first electrode 10 connected thereto may be of an integral structure. When the third electrode 101 and the first electrode 10 connected thereto are of an integral structure, there is no obvious boundary between the third electrode 101 and the first Electrode 10. A region of the conductive layer surrounded by the dielectric layer 103 is the third electrode 101, and a region of the conductive layer not surrounded by the dielectric layer 103 is the first electrode 10. The first electrode connected to the third electrode 101 may be a source electrode of the transistor.

In an exemplary embodiment of the present disclosure, as shown in FIG. 2B, the fourth electrodes 102 of the capacitors of a column of memory cells located in the same layer and arranged along the second direction may be a common structure or an integral structure.

In an exemplary embodiment of the present disclosure, as shown in FIG. 2D, the fourth electrodes 102 of the capacitors of a column of memory cells located in different layers and arranged along a direction perpendicular to the substrate 1 may be a common structure or an integral structure.

In an exemplary embodiment of the present disclosure, fourth electrodes of capacitors of a column of memory cells located in the same layer and arranged along the second direction are a common structure or are an integral structure, and fourth electrodes of capacitors of a column of memory cells located in different layers and arranged along a direction perpendicular to the substrate may be a common structure or an integral structure.

In an exemplary embodiment of the present disclosure, the third electrode may be formed by or include a conductive material, and the conductive material may be, for example, one of a doped semiconductor material, a conductive metal nitride, a metal material, and a metal-semiconductor compound, such as tungsten (W), or the like; and exemplarily, a material of the gate electrode may include, but is not limited to, at least one of the followings: Indium Tin Oxide (ITO), a composite film layer of TiN and W, Aluminum doped Zinc Oxide (AZO), and Indium Zinc Oxide (IZO).

In an exemplary embodiment of the present disclosure, the material of the fourth electrode may include, but is not limited to, at least one of the followings: polysilicon, metal (e.g. tungsten, etc.), doped monocrystalline silicon (doping element may be As, doping concentration may be 1e19).

In an exemplary embodiment of the present disclosure, the material of the dielectric layer may be silicon oxide or a High-K dielectric material, i.e., a dielectric material of dielectric constant K≥3.9. The High-K dielectric material may include, but is not limited to, at least one of the followings: aluminum oxide (Al₂O₃), and hafnium oxide (HfO₂).

In an exemplary embodiment of the present disclosure, the 3D stacked semiconductor device may be a 3D memory, such as a 3D DRAM memory or the like. The 3D memory may be of a 1T1C or 2T (including a read transistor and a write transistor) structure.

An embodiment of the present disclosure also provides a method for manufacturing a 3D stacked semiconductor device, and the 3D stacked semiconductor device shown in FIG. 2A to FIG. 2D, as provided by the above exemplary embodiments of the present disclosure, may be manufactured through the method.

The 3D stacked semiconductor device includes: a plurality of memory cells, distributed in different layers, stacked periodically along a direction perpendicular to the substrate. Each layer includes a plurality of columns of memory cells, and the memory cell includes a transistor. The transistor includes a first electrode, a second electrode, a semiconductor layer arranged between the first electrode and the second electrode, and a gate electrode. The first electrode and the second electrode are separated in a first direction parallel to the substrate. The gate electrode extends along a second direction in a plane parallel to the substrate, and the gate electrode includes a sidewall extending along the second direction and two end surfaces, wherein one end surface is configured to be connected with a word line, and the other end surface extends into a hollow annular semiconductor layer; the first direction intersects with the second direction.

The method includes: forming a first electrode and a second electrode of a transistor on the substrate; forming a bit line connected to a plurality of second electrodes; forming a hollow annular semiconductor layer between the first electrode and the second electrode, and a gate electrode with one end surface extending into the semiconductor layer; and forming a word line connected to the other end surfaces of a plurality of gate electrodes.

In an exemplary embodiment of the present disclosure, forming the first electrode and the second electrode of the transistor on the substrate and forming the bit line connected to the plurality of the second electrodes may include:
sequentially and alternately depositing first insulation layers and second insulation layers on the substrate;
performing a patterning etching on the first insulation layers and the second insulation layers, wherein a patterned first insulation layer and a patterned second insulation layer include a dummy bit line region extending along the second direction, a dummy electrode region extending from a side of the dummy bit line region towards the first direction, a dummy channel and gate region extending from a side of the dummy electrode region towards the second direction; wherein the dummy electrode region includes a first electrode region located between two adjacent dummy channel and gate regions, and a second electrode region located between the dummy bit line region, and the dummy channel and gate region; one end of the dummy channel and gate region is connected with the dummy electrode region;
etching to remove a patterned second insulation layer of the first electrode region, obtaining a first electrode groove, and forming the first electrode in the first electrode groove; and
etching to remove patterned second insulation layers of the second electrode region and the dummy bit line region, obtaining a second electrode groove and a bit line groove, respectively, and forming the second electrode and the bit line connected to the second electrode in the second electrode groove and the bit line groove, respectively.

In an exemplary embodiment of the present disclosure, two ends of the dummy electrode region are respectively connected to two adjacent dummy bit line regions, and each dummy electrode region is connected to two dummy channel and gate regions; the memory cell further includes a capacitor, which includes a third electrode and a fourth electrode.

Etching to removing the patterned second insulation layer of the first electrode region, obtaining the first electrode groove, and forming the first electrode in the first electrode groove, and the forming process of the capacitor may include:
filling a stacked structure formed by the patterned first insulation layer and the patterned second insulation layer by using the first insulation layer;
etching the stacked structure along a direction towards the substrate, forming a first groove in the first electrode region extending along the second direction and penetrating through each patterned second insulation layer, wherein the first groove separates the first electrode region into two portions, and the first groove exposes end surfaces of separated first electrode regions on both sides;
laterally etching the patterned second insulation layer on both sides of the first groove to remove the patterned second insulation layer of the first electrode region, and obtaining first electrode grooves on both sides of the first groove;
depositing a first conductive layer in the first electrode groove;
etching the first insulation layer on both sides of the first groove to expose a side surface, with a set depth, of the first conductive layer; wherein an exposed region of the first conductive layer is a third electrode of the capacitor, and an unexposed region is the first electrode of the transistor; and
sequentially forming a dielectric layer and a fourth electrode of the capacitor on a surface of the third electrode.

In an exemplary embodiment of the present disclosure, the etching to removing the patterned second insulation layers of the second electrode region and the dummy bit line region, obtaining the second electrode groove and the bit line groove, respectively, and forming the second electrode and the bit line connected to the second electrode in the second electrode groove and the bit line groove, respectively, may include:
etching the patterned first insulation layer and second insulation layer distributed in a stacked mode along a direction towards the substrate, forming an initial bit line groove in the dummy bit line region extending along the second direction and penetrating through each patterned second insulation layer, laterally etching the patterned second insulation layers on both sides of the initial bit line groove to remove the patterned second insulation layers of the second electrode region and the dummy bit line region, wherein a portion of a sidewall of the initial bit line groove extends into the patterned second insulation layer to obtain a bit line groove located in the dummy bit line region and a second electrode groove located in the second electrode region;
depositing a second conductive layer in the bit line groove and the second electrode groove, and forming a second electrode in the second conductive layer located in the second electrode groove; and
etching the second conductive layer located in the bit line groove along a direction towards the substrate, forming a second groove extending along the second direction and penetrating through each layer bit line groove, wherein the second groove separates the second conductive layer in the bit line groove into two bit lines, and each bit line is connected with a separated column of second electrodes along the second direction; and depositing the first insulation layer in the second groove.

In an exemplary embodiment of the present disclosure, forming the hollow annular semiconductor layer between the first electrode and the second electrode, and the gate electrode with one end surface extending into the semiconductor layer, and forming the word line connected to the other end surfaces of the plurality of the gate electrodes, may include:
etching to remove a patterned second insulation layer of the dummy channel and the gate region, obtaining a channel groove, a gate electrode groove and a word line groove arranged sequentially along a direction away from the dummy electrode region, and sequentially forming the hollow annular semiconductor layer, the gate electrode with one end surface extending into the semiconductor layer, and the word line connected with the other end surface of the gate electrode in the channel groove, the gate electrode groove and the word line groove.

In an exemplary embodiment of the present disclosure, the forming the hollow annular semiconductor layer between the first electrode and the second electrode, and the gate electrode with one end surface extending into the semiconductor layer, and forming the word line connected to the other end surfaces of the plurality of the gate electrodes, may include:
etching a patterned first insulation layer and a patterned second insulation layer on a side of the dummy channel and gate region away from the dummy electrode region, forming a word line groove penetrating through each patterned second insulation layer on the side of the dummy channel and gate region away from the dummy electrode region, wherein the word line groove exposes an end surface of the patterned second insulation layer;
etching the patterned second insulation layer in the word line groove to remove a patterned second insulation layer in the whole dummy channel and gate region, and obtaining a channel groove located in the dummy channel and gate region and connected with one end of the dummy electrode region, and a gate electrode groove located between the channel groove and the word line groove;
sequentially forming a semiconductor layer and a third insulation layer on inner walls of the word line groove, the gate electrode groove and the channel groove, and filling a third conductive layer in remaining spaces of the word line groove, the gate electrode groove and the channel groove; and
etching to remove a third conductive layer and a third insulation layer in the word line groove, etching to remove a semiconductor layer in the word line groove and the gate electrode groove, and depositing a third insulation layer on an inner wall of the gate electrode groove, and depositing a third conductive layer in the word line groove; wherein a semiconductor layer retained in the channel groove serves as a semiconductor layer of the transistor, a third conductive layer located in the gate electrode groove and the channel groove serves as a gate electrode of the transistor, a third conductive layer located in the word line groove serves as a word line, and a third insulation layer located in the channel groove and the gate electrode groove forms a gate insulation layer that insulates the semiconductor layer from the gate electrode and the word line.

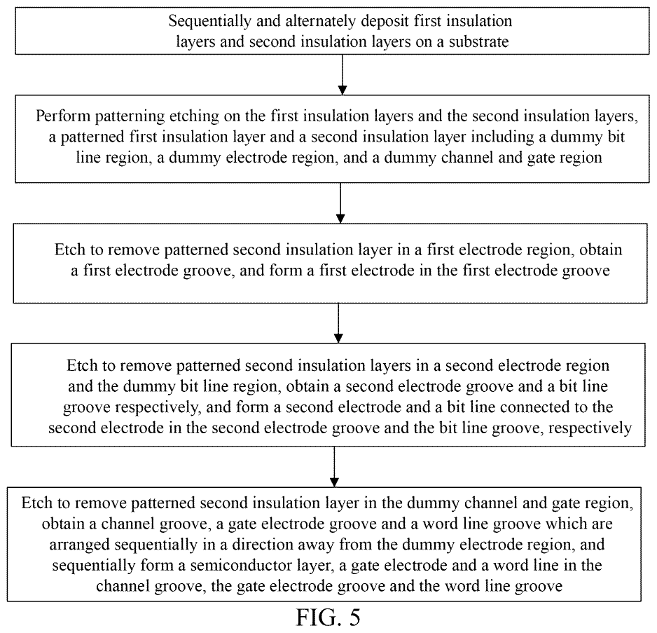

FIG. 5 is a process flowchart of a method for manufacturing a 3D stacked semiconductor device according to an exemplary embodiment of the present disclosure.

As shown in FIG. 5, in an exemplary embodiment of the present disclosure, the method for manufacturing a 3D stacked semiconductor device may include:
sequentially and alternately depositing first insulation layers and second insulation layers on the substrate;
performing a patterning etching on the first insulation layers and the second insulation layers, wherein a patterned first insulation layer and a patterned second insulation layer include a dummy bit line region extending along the second direction, a dummy electrode region extending from a side of the dummy bit line region towards the first direction, a dummy channel and gate region extending from a side of the dummy electrode region towards the second direction; wherein the dummy electrode region includes a first electrode region located between two adjacent dummy channel and gate regions, and a second electrode region located between the dummy bit line region, and the dummy channel and gate region; one end of the dummy channel and gate region is connected with the dummy electrode region;
etching to remove a patterned second insulation layer of the first electrode region, obtaining a first electrode groove, and forming the first electrode in the first electrode groove; and
etching to remove patterned second insulation layers of the second electrode region and the dummy bit line region, obtaining a second electrode groove and a bit line groove, respectively, and forming the second electrode and the bit line connected to the second electrode in the second electrode groove and the bit line groove, respectively;
etching to remove a patterned second insulation layer of the dummy channel and the gate region, obtaining a channel groove, a gate electrode groove and a word line groove arranged sequentially along a direction away from the dummy electrode region, and sequentially forming a hollow annular semiconductor layer, a gate electrode with one end surface extending into the semiconductor layer, and a word line connected with the other end surface of the gate electrode in the channel groove, the gate electrode groove and the word line groove.

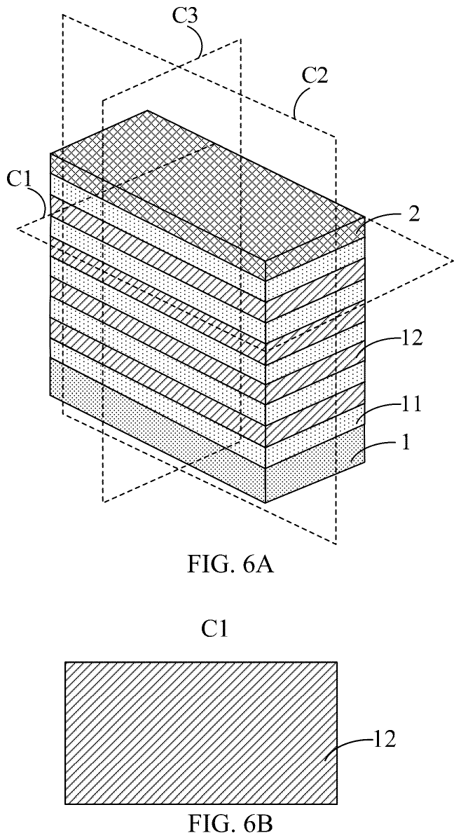

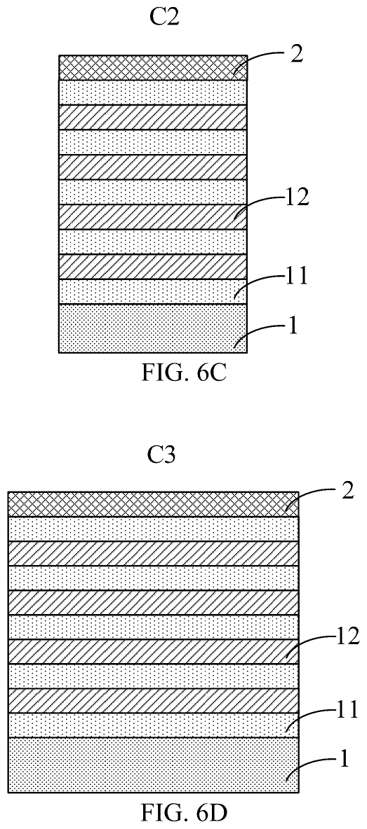

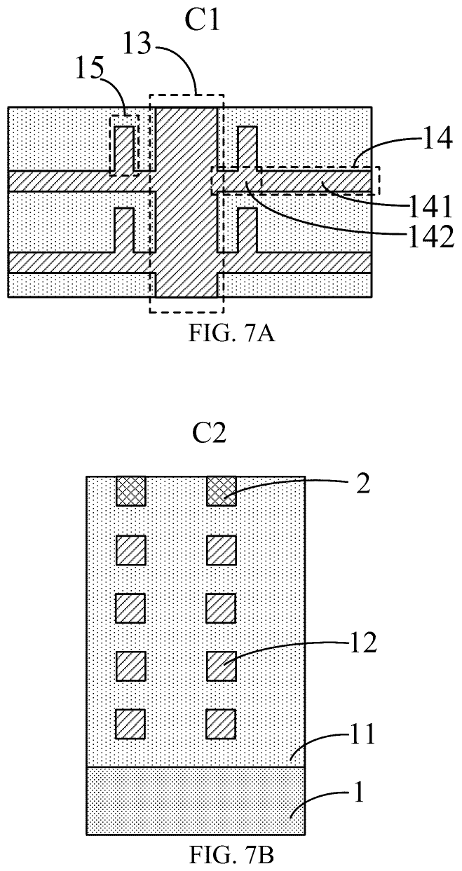

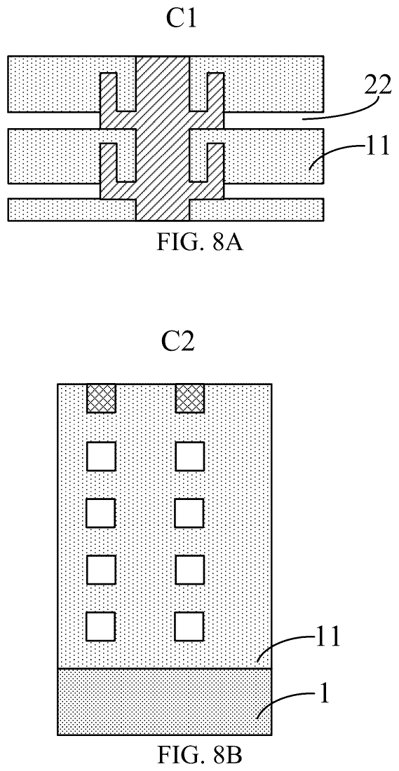

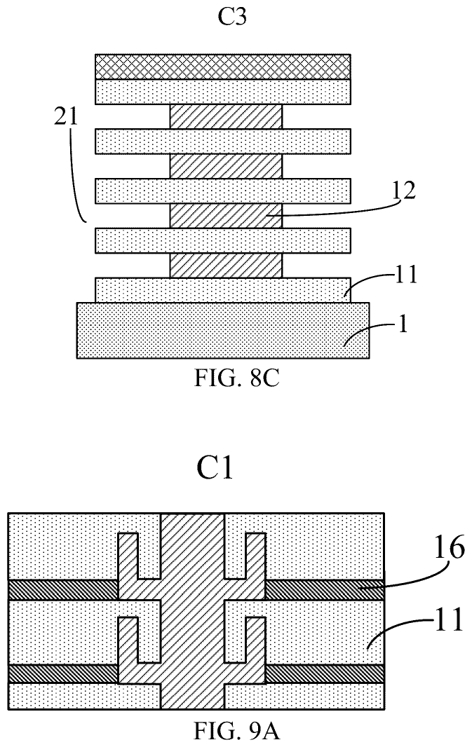

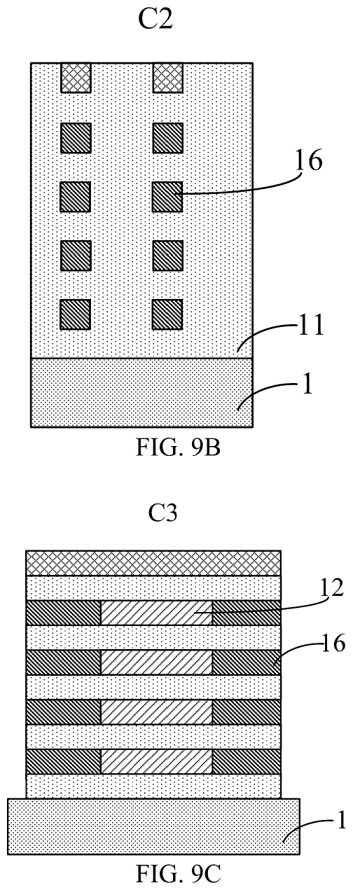

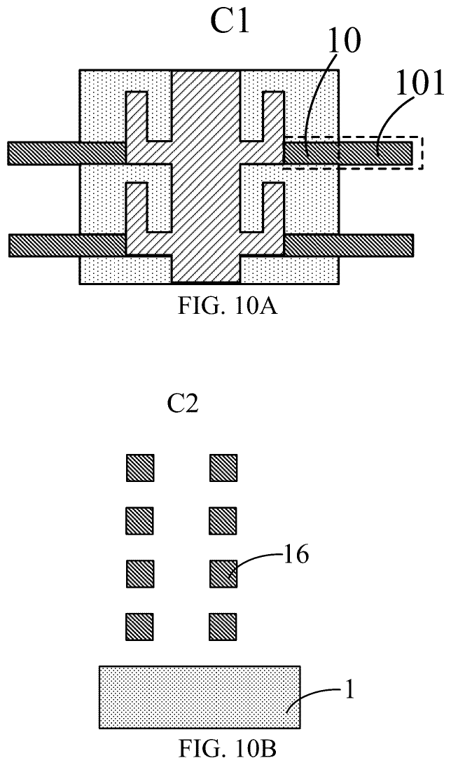

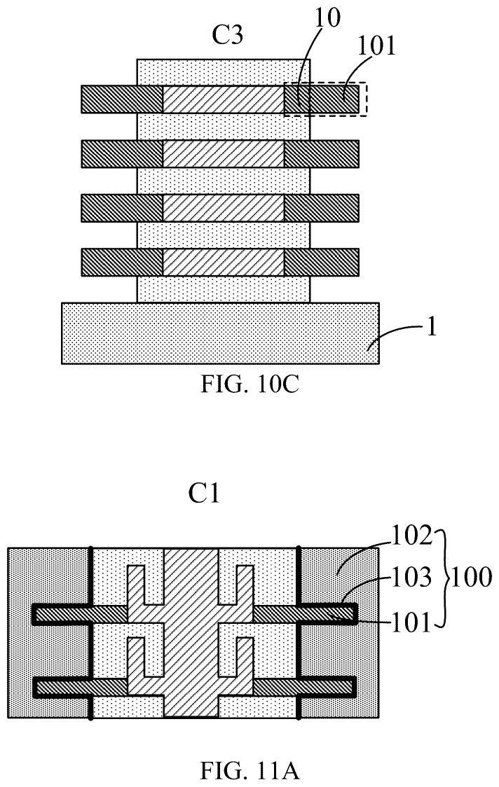

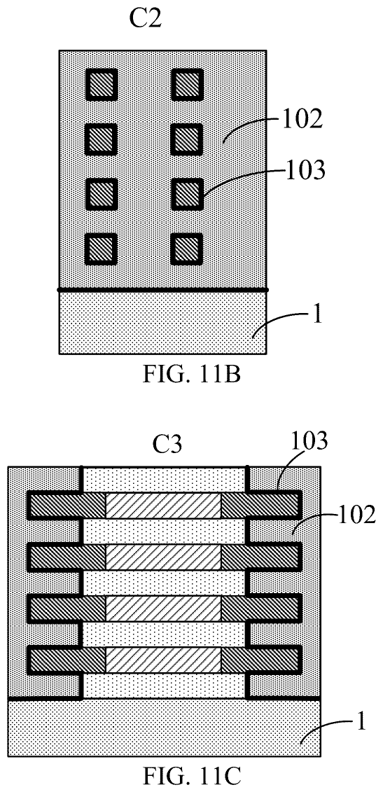

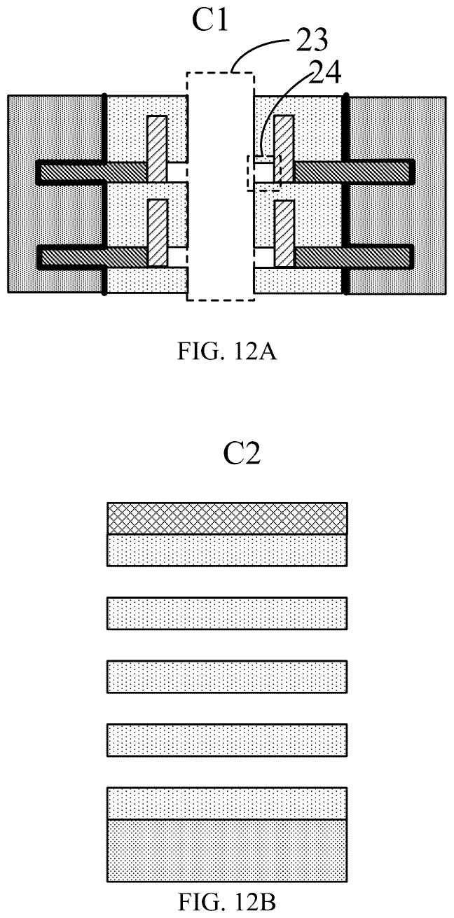

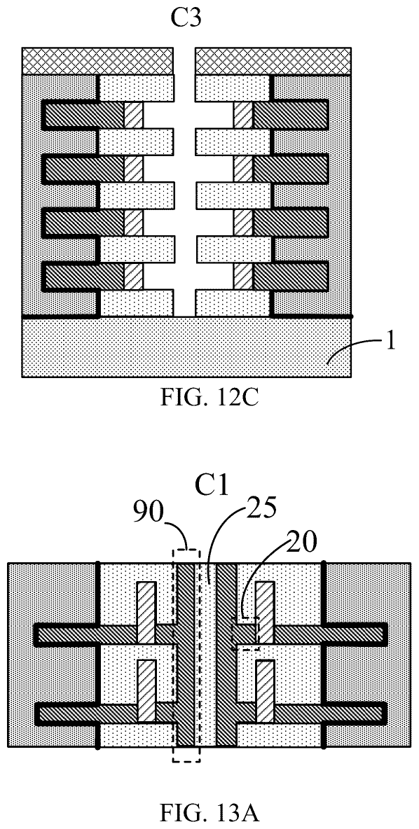

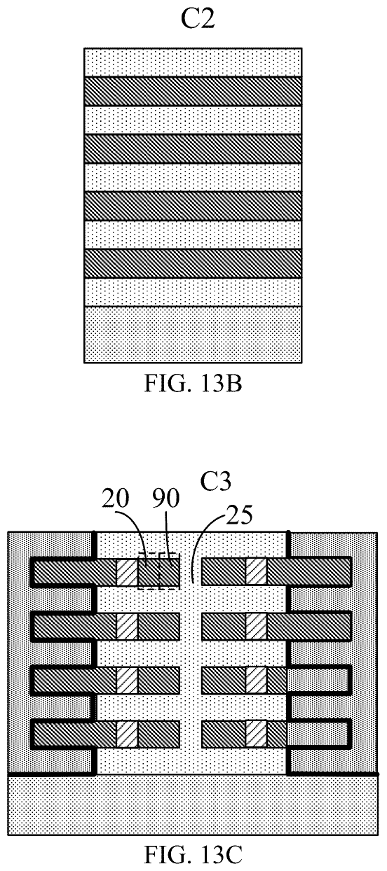

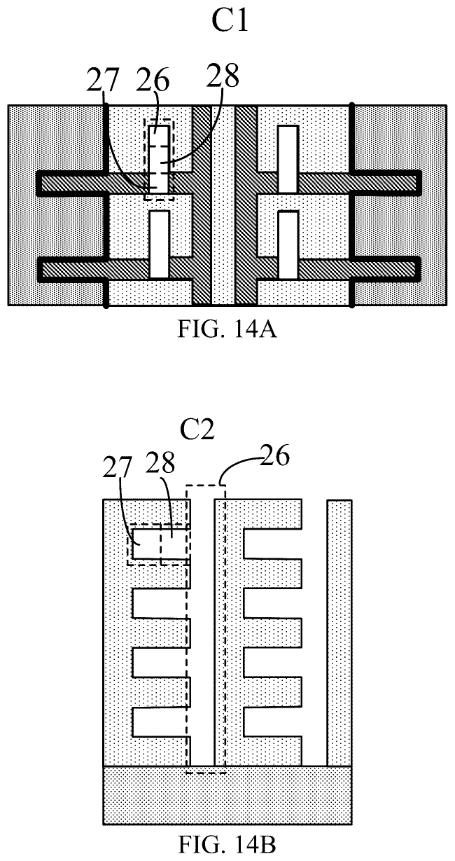

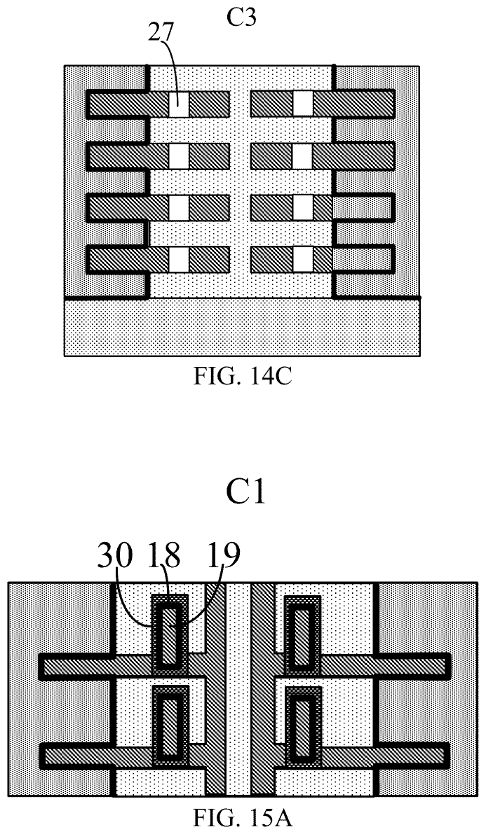

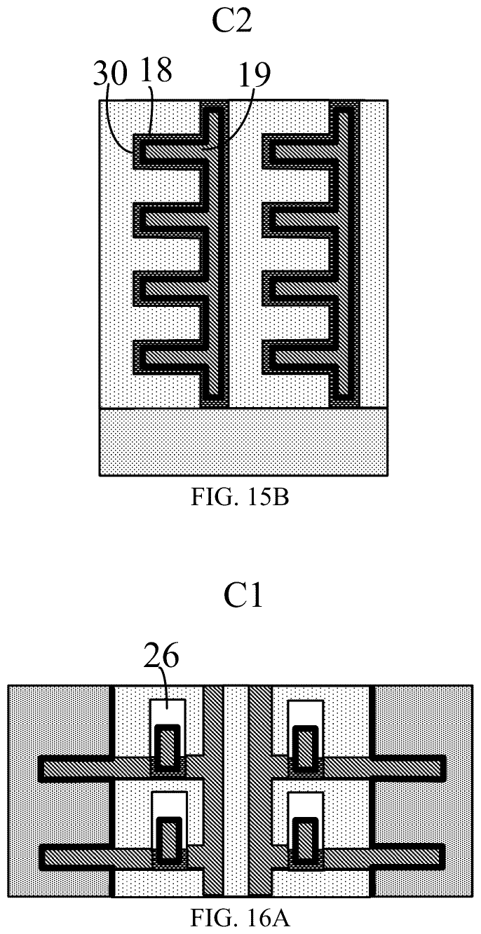

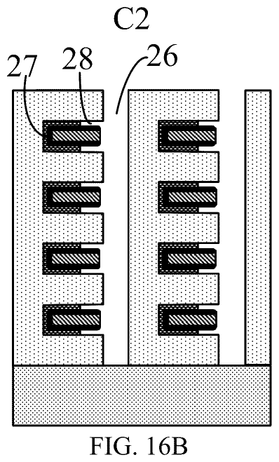

FIG. 6A is a schematic diagram of a three-dimensional structure after a stacked structure a 3D stacked semiconductor device is formed by using a manufacturing method according to an exemplary embodiment of the present disclosure. FIG. 6B is a cross-sectional view of the structure shown in FIG. 6A on a C1 plane parallel to the substrate. FIG. 6C is a cross-sectional view of the structure shown in FIG. 6A on a C2 plane perpendicular to the substrate. FIG. 6D is a cross-sectional view of the structure shown in FIG. 6A on a C3 plane perpendicular to the substrate. FIG. 7A is a cross-sectional view after a patterned second insulation layer of a 3D stacked semiconductor device is formed by using a manufacturing method on a C1 plane parallel to the substrate according to an exemplary embodiment of the present disclosure. FIG. 7B is a cross-sectional view of the structure shown in FIG. 7A on a C2 plane perpendicular to the substrate. FIG. 8A is a cross-sectional view after a first electrode groove of a 3D stacked semiconductor device is formed by using a manufacturing method on a C1 plane parallel to the substrate according to an exemplary embodiment of the present disclosure. FIG. 8B is a cross-sectional view of the structure shown in FIG. 8A on a C2 plane perpendicular to the substrate. FIG. 8C is a cross-sectional view of the structure shown in FIG. 8A on a C3 plane perpendicular to the substrate. FIG. 9A is a cross-sectional view after a first conductive layer of a 3D stacked semiconductor device is formed by using a manufacturing method on a C 1 plane parallel to the substrate according to an exemplary embodiment of the present disclosure. FIG. 9B is a cross-sectional view of the structure shown in FIG. 9A on a C2 plane perpendicular to the substrate. FIG. 9C is a cross-sectional view of the structure shown in FIG. 9A on a C3 plane perpendicular to the substrate. FIG. 10A is a cross-sectional view after a third electrode of a 3D stacked semiconductor device is formed by using a manufacturing method on a C1 plane parallel to the substrate according to an exemplary embodiment of the present disclosure. FIG. 10B is a cross-sectional view of the structure shown in FIG. 10A on a C2 plane perpendicular to the substrate. FIG. 10C is a cross-sectional view of the structure shown in FIG. 10A on a C3 plane perpendicular to the substrate. FIG. 11A is a cross-sectional view after a forth electrode of a 3D stacked semiconductor device is formed by using a manufacturing method on a C1 plane parallel to the substrate according to an exemplary embodiment of the present disclosure. FIG. 11B is a cross-sectional view of the structure shown in FIG. 11A on a C2 plane perpendicular to the substrate. FIG. 11C is a cross-sectional view of the structure shown in FIG. 11A on a C3 plane perpendicular to the substrate. FIG. 12A is a cross-sectional view after a second electrode groove of a 3D stacked semiconductor device is formed by using a manufacturing method on a C1 plane parallel to the substrate according to an exemplary embodiment of the present disclosure. FIG. 12B is a cross-sectional view of the structure shown in FIG. 12A on a C2 plane perpendicular to the substrate. FIG. 12C is a cross-sectional view of the structure shown in FIG. 12A on a C3 plane perpendicular to the substrate. FIG. 13A is a cross-sectional view after a bit line of a 3D stacked semiconductor device is formed by using a manufacturing method on a C1 plane parallel to the substrate according to an exemplary embodiment of the present disclosure. FIG. 13B is a cross-sectional view of the structure shown in FIG. 13A on a C2 plane perpendicular to the substrate. FIG. 13C is a cross-sectional view of the structure shown in FIG. 13A on a C3 plane perpendicular to the substrate. FIG. 14A is a cross-sectional view after a channel groove of a 3D stacked semiconductor device is formed by using a manufacturing method on a C1 plane parallel to the substrate according to an exemplary embodiment of the present disclosure. FIG. 14B is a cross-sectional view of the structure shown in FIG. 14A on a C2 plane perpendicular to the substrate. FIG. 14C is a cross-sectional view of the structure shown in FIG. 14A on a C3 plane perpendicular to the substrate. FIG. 15A is a cross-sectional view after a semiconductor layer of a 3D stacked semiconductor device is formed by using a manufacturing method on a C1 plane parallel to the substrate according to an exemplary embodiment of the present disclosure. FIG. 15B is a cross-sectional view of the structure shown in FIG. 15A on a C2 plane perpendicular to the substrate. FIG. 16A is a cross-sectional view after a semiconductor layer of a 3D stacked semiconductor device in a word line groove is removed by using a manufacturing method on a C1 plane parallel to the substrate according to an exemplary embodiment of the present disclosure. FIG. 16B is a cross-sectional view of the structure shown in FIG. 16A on a C2 plane perpendicular to the substrate.

As shown in FIGS. 2A-2D and 6A-16B, in an exemplary embodiment, the method for manufacturing the 3D stacked semiconductor device may include following acts.

At S10, the first insulation layers 11 and the second insulation layers 12 are deposited sequentially and alternately on the substrate 1 to obtain a stacked structure formed by the first insulation layers 11 and the second insulation layers 12 distributed in a stacked mode, as shown on FIGS. 6a, 6b, 6c and 6d.

Here, FIG. 6B is a cross-sectional view on a C1 plane parallel to the substrate, and the C1 plane passes through the second insulation layer; FIG. 6C is a cross-sectional view on a C2 plane perpendicular to the substrate; FIG. 6D is a cross-sectional view on a C3 plane perpendicular to the substrate, and the C3 plane is perpendicular to the C2 plane; and positions of the C1 plane, the C2 plane, and the C3 plane may be as shown in FIG. 6A, and the C1 plane, the C2 plane, and the C3 plane hereafter have the same direction as the C1 plane, the C2 plane, and the C3 plane in FIG. 6A, but the taken positions may be different.

In an exemplary embodiment of the present disclosure, the substrate may be a semiconductor substrate, which may be, for example, a silicon substrate.

In an exemplary embodiment of the present disclosure, the materials of the first insulation layer and the second insulation layer may each independently be selected from one or more of silicon oxide (e.g. SiO₂), silicon oxynitride (SiON), silicon nitride (SiN), silicon carbonitride (SiCN), and the materials of the first insulation layer and the second insulation layer are different, so that when the second insulation layer is etched and removed later, the first insulation layer and the second insulation layer may have different etching rates, thereby the second insulation layer is removed while the first insulation layer is retained. For example, in this embodiment, the material of the first insulation layer may be silicon oxide, and the material of the second insulation layer may be silicon nitride.

The stacked structure shown in FIG. 6A includes five first insulation layers 11 and four second insulation layers 12, only as an example, and in some other embodiments, the stacked structure may include more or fewer first insulation layers 11 and second insulation layers 12 arranged alternatively.

At S20, a hard mask 2 is deposited on the top surface of the stacked structure, and it is photoetched and etched, so that a patterning etching is performed on the stacked structure by taking the hard mask 2 with a photoresist pattern as a mask and using an isotropic etching process. The patterned first insulation layer 11 and second insulation layer 12 include a dummy bit line region 13 extending along the second direction, a dummy electrode region 14 extending from a side of the dummy bit line region 13 towards the first direction, and a dummy channel and gate region 15 extending from a side of the dummy electrode region 14 towards the second direction. The dummy electrode region 14 includes a first electrode region 141 located between two adjacent dummy channel and gate regions 15, and a second electrode region 142 located between the dummy bit line region 13 and the dummy channel and gate region 15. Both ends of the dummy electrode region 14 may be respectively connected with two adjacent dummy bit line regions 13, and each dummy electrode region 14 may be connected with two dummy channel and gate regions 15; one end of the dummy channel and gate region 15 is connected with the dummy electrode region 14. A stacked structure formed by the patterned first insulation layer 11 and the patterned second insulation layer 12 is filled with the first insulation layer 11, and the first insulation layer 11 filled here is planarized through Chemical Mechanical Polishing (CMP), as shown in FIG. 7A and FIG. 7B; here, FIG. 7A is a cross-sectional view on a C1 plane parallel to the substrate, and the C1 plane passes through the patterned second insulation layer; FIG. 7B is a cross-sectional view on a C2 plane perpendicular to the substrate, and the C2 plane passes through the first electrode region; and a cross-sectional view on a C3 plane of the structure shown in FIG. 7A is the same as that in FIG. 6D.

At S30, the stacked structure filled with the first insulation layer 11 is etched along the direction towards the substrate 1 to form a first groove 21 in the first electrode region extending along the second direction and penetrating through each patterned second insulation layer 12, the first groove 21 separates the first electrode region into two portions, and the first groove 21 exposes the end surfaces of the separated first electrode regions on both sides; a hard mask covering the substrate 1 is deposited, and the patterned second insulation layer 12 on both sides of the first groove 21 is isotropically etched such that the patterned second insulation layer 12 of the first electrode region is removed to obtain first electrode grooves 22 located on both sides of the first groove 21, as shown in FIGS. 8A, 8B and 8C. Here, FIG. 8A is a cross-sectional view on a C1 plane parallel to the substrate, and the C1 plane passes through the patterned second insulation layer; FIG. 8B is a cross-sectional view on a C2 plane perpendicular to the substrate, and the C2 plane passes through the first electrode groove; and FIG. 8C is a cross-sectional view on a C3 plane perpendicular to the substrate, and the C3 plane passes through the first electrode groove.

At S40, a first conductive layer 16 covering the first groove 21 and the first electrode groove 22 is deposited on the substrate 1, the first conductive layer 16 is anisotropically etched such that the first conductive layer 16 in the first groove 21 is removed and only the first conductive layer 16 in the first electrode groove 22 is retained, as shown in FIGS. 9A, 9B and 9C. Here, FIG. 9A is a cross-sectional view on a C 1 plane parallel to the substrate, and the C1 plane passes through the patterned second insulation layer; FIG. 9B is a cross-sectional view on a C2 plane perpendicular to the substrate, and the C2 plane passes through the first electrode groove; and FIG. 9C is a cross-sectional view on a C3 plane perpendicular to the substrate, and the C3 plane passes through the first electrode groove.

For example, the first conductive layer 16 may be deposited by using an Atomic Layer Deposition (ALD) process, so that the first conductive layer 16 fully fills the first electrode groove 22.

At S50, the first insulation layer 11 on both sides of the first groove 21 is etched, so that the side surface with a set depth, of the first conductive layer 16 is exposed; and an exposed region of the first conductive layer 16 is the third electrode 101 of the capacitor, and an unexposed region is the first electrode 10 of the transistor.

Exemplarily, the above S50 may include following acts.

At S51, the first insulation layer 11 is filled in the first groove 21, and CMP is performed;

At S52, a hard mask 2 is deposited on the surface of the substrate 1, the hard mask 2 is photoetched and etched, the first conductive layer 16 and the first insulation layer 11 distributed in a stacked mode are anisotropically etched, so that a first groove extending along the second direction is re-formed, and the first groove here penetrates through each of the first conductive layers 16 located in the first electrode region.

At S53, the first insulation layer 11 on both sides of the first groove is isotropically etched, so that the side surface with a set depth, of the first conductive layer 16 is exposed, wherein the set length is a length of the third electrode of the capacitor, that is, the exposed end of the first conductive layer 16 is subsequently used as the third electrode 101 of the capacitor, and the unexposed end of the first conductive layer 16 is used as the first electrode 10 of the transistor; a hard mask on the top surface of the substrate 1 is etched and removed, as shown in FIGS. 10A, 10B, and 10C. Here, FIG. 10A is a cross-sectional view on a C1 plane parallel to the substrate and the C1 plane passes through the patterned second insulation layer; FIG. 10B is a cross-sectional view on a C2 plane perpendicular to the substrate, and the C2 plane passes through the first electrode groove; and FIG. 10C is a cross-sectional view on a C3 plane perpendicular to the substrate, and the C3 passes through the first electrode groove.

At S60, a dielectric layer 103 and a conductive film layer surrounding the sidewall and end surface of the third electrode 101 are sequentially deposited on the surface of the third electrode 101, the conductive film layer forms a fourth Electrode 102, and one third electrode 101, one fourth electrode 102 and one dielectric layer 103 form a capacitor 100, as shown in FIGS. 11A, 11B and 11C. Here FIG. 11A is a cross-sectional view on a C1 plane parallel to the substrate and the C1 plane passes through the patterned second insulation layer; FIG. 11B is a cross-sectional view on a C2 plane perpendicular to the substrate, and the C2 plane passes through the first electrode groove; and FIG. 11C is a cross-sectional view on a C3 plane perpendicular to the substrate, and the C3 plane passes through the first electrode groove.

At S70, a hard mask is deposited on the top surface of the substrate 1, then the hard mask is photoetched and etched, the patterned first insulation layer and the patterned second insulation layer which are distributed in a stacked mode are etched along a direction towards the substrate 1 to form an initial bit line groove in the dummy bit line region extending along the second direction and penetrating through each patterned second insulation layer, and the patterned second insulation layer on both sides of the initial bit line groove is etched laterally so that the patterned second insulation layers of the second electrode region and the dummy bit line region are removed, and a portion of the sidewall of the initial bit line groove extends into the patterned second insulation layer to obtain a bit line groove 23 located in the dummy bit line region and a second electrode groove 24 located in the second electrode region, as shown in FIGS. 12A, 12B and 12C. Here FIG. 12A is a cross-sectional view on a C1 plane parallel to the substrate, and the C1 plane passes through the patterned second insulation layer; FIG. 12B is a cross-sectional view on a C2 plane perpendicular to the substrate, and the C2 plane passes through the second electrode groove; and FIG. 12C is a cross-sectional view on a C3 plane perpendicular to the substrate, and the C3 plane passes through the second electrode groove.

At S80, a second conductive layer is deposited in the bit line groove 23 and the second electrode groove 24, and the second conductive layer in the second electrode groove 24 forms the second electrode 20; the second conductive layer in the bit groove is anisotropically etched along a direction towards the substrate 1 to form a second groove 25 extending along the second direction and penetrating through various bit grooves, the second groove 25 separates the second conductive layer in the bit groove 23 into two bit lines 90, and each of the bit lines 90 is connected to a separated column of second electrodes 20 along the second direction; the first insulation layer is deposited in the second groove 25, as shown in FIGS. 13A, 13B, and 13C. Here, FIG. 13A is a cross-sectional view on a C1 plane parallel to the substrate, and the C1 plane passes through the patterned second insulation layer; FIG. 13B is a cross-sectional view on a C2 plane perpendicular to the substrate, and the C2 plane passes through the bit line; and FIG. 13C is a cross-sectional view on a C3 plane perpendicular to the substrate, and the C3 plane passes through the second electrode.

At S90, the patterned first insulation layer and the patterned second insulation layer on a side of the dummy channel and gate region away from the dummy electrode region are etched to form a word line groove 26 penetrating each patterned second insulation layer on the side of the dummy channel and gate region away from the dummy electrode region, and the word line groove 26 exposes the end surface of the patterned second insulation layer 12; the patterned second insulation layer 12 in the word groove 26 is etched so that the patterned second insulation layer 12 of the entire dummy channel and gate region is removed to obtain a channel groove 27 located in the dummy channel and gate region and connected to one end of the dummy electrode region, and a gate electrode groove 28 located between the channel groove 27 and the word groove 26, as shown in FIGS. 14A, 14B and 14C. Here, FIG. 14A is a cross-sectional view on a C1 plane parallel to the substrate, and the C1 plane passes through the bit line; FIG. 14B is a cross-sectional view on a C2 plane perpendicular to the substrate, and the C2 plane passes through the channel groove; and FIG. 14C is a cross-sectional view on a C3 plane perpendicular to the substrate, and the C1 plane passes through the second electrode.

At S100, a semiconductor layer 30 and a third insulation layer 18 are sequentially deposited on the inner walls of the word line groove 26, the gate electrode groove 28, and the channel groove 27, and a third conductive layer 19 is filled in the remaining spaces of the word line groove 26, the gate electrode groove 28, and the channel groove 27, as shown in FIG. 15A and FIG. 15B. Here, FIG. 15A is a cross-sectional view on a C1 plane parallel to the substrate, and the C1 plane passes through the bit line; FIG. 15B is a cross-sectional view on a C2 plane perpendicular to the substrate, and the C2 plane passes through the channel groove; and the cross-sectional view of the structure shown in FIG. 15A on a C3 plane perpendicular to the substrate is the same as that in FIG. 2D, in a case that the intercepted positions of the C3 plane are the same.

At S110, a hard mask is deposited on the surface of the substrate 1, the hard mask is photoetched and etched, then the third conductive layer 19 and the third insulation layer 18 in the word groove 26 is isotropically etched and removed, and the semiconductor layer 30 in the word groove 26 and the gate electrode groove 28 is isotropically etched and removed, as shown in FIG. 16A and FIG. 16B. Here, FIG. 16A is a cross-sectional view on a C1 plane parallel to the substrate, and the C1 plane passes through the bit line; FIG. 16B is a cross-sectional view on a C2 plane perpendicular to the substrate, and the C2 plane passes through the channel groove; the cross-sectional view of the structure shown in FIG. 16A on a C3 plane perpendicular to the substrate is the same as that in FIG. 2D in a case that the intercepted positions of the C3 plane are the same.

At S120, the third insulation layer 18 is re-deposited on the inner wall of the gate electrode groove 28, and the third conductive layer 19 is re-deposited in the word line groove 26; the semiconductor layer located in the channel groove 27 is the semiconductor layer 30 of the transistor, the third conductive layer 19 located in the gate electrode groove 28 and the channel groove 27 serves as the gate electrode 40 of the transistor, the third conductive layer 19 located in the word line groove 26 serves as the word line 80, and the third insulation layer 18 located in the channel groove 27 and the gate electrode groove 28 forms a gate insulation layer 50 that insulates the semiconductor layer 30 from the gate electrode 40 and the word line 80.

In the method for manufacturing the 3D stacked semiconductor device according to an embodiment of the present disclosure, firstly insulation layers of two different materials are formed, then a patterning etching is performed on one of the insulation layers, the etched pattern includes a dummy bit line region (a region where bit lines are subsequently formed), a dummy electrode region (a region where source electrodes and drain electrodes of transistors are subsequently formed), and a dummy channel and gate region (a region where semiconductor layers, gate electrodes and word lines of transistors are subsequently formed), and then the patterned insulation layers of the above regions are respectively replaced by using corresponding materials to form real bit lines, source electrodes and drain electrodes of transistors, semiconductor layers and gate electrodes, and word lines. The whole manufacturing process does not involve etching the stacked structure of metal/insulation layer, and the parasitic MOS is located in the subsequent region where word lines are formed. The parasitic MOS may be removed by opening word line grooves perpendicular to the substrate, thus reducing the difficulty of the process module for removing parasitic MOS, and simplifying the manufacturing process of semiconductor devices.

An embodiment of the present disclosure also provides an electronic device including the transistor or the 3D stacked semiconductor device as provided above in embodiments of the present disclosure.

In exemplary embodiments of the present disclosure, the electronic device may be a memory device, a smart phone, a computer, a tablet computer, an artificial intelligence device, a wearable device, a mobile power supply, or the like. The storage device may include a memory in a computer or the like, which is not limited here.

Although implementations disclosed in the present disclosure are as described above, the described contents are only implementations used for facilitating understanding of the present disclosure, but are not intended to limit the present disclosure. Without departing from the spirit and scope disclosed in the present disclosure, any person skilled in the art to which the present disclosure belongs may make any modifications and changes in the implementation form and details, however the protection scope of the present disclosure shall still be defined by the appended claims.

1. A transistor, comprising: a first electrode and a second electrode arranged on a substrate, a semiconductor layer arranged between the first electrode and the second electrode, and a gate electrode insulated from the semiconductor layer;
wherein the first electrode and the second electrode are separated in a first direction parallel to the substrate; the gate electrode comprises a side wall and two end surfaces, wherein one end surface of the two end surfaces is configured to be connected with a word line; at least a portion of the side wall of the gate electrode is surrounded by the semiconductor layer; and an extension direction of the gate electrode intersects with an extension direction of the word line.

2. The transistor according to claim 1, wherein the gate electrode extends along a second direction parallel to the substrate, and the first direction intersects with the second direction; and
the word line extends along the first direction or a direction perpendicular to the substrate.

3. The transistor according to claim 1, wherein the other end surface of the gate electrode is surrounded by the semiconductor layer.

4. The transistor according to claim 3, wherein the semiconductor layer surrounding the gate electrode forms a hollow tubular structure; the tubular structure has a side surface, a bottom surface and an opening, wherein the side surface comprises two separated electrode contact regions, which are respectively in contact with the first electrode and the second electrode, and a region of the side surface and the bottom surface of the tubular structure located between the first electrode and the second electrode is a channel region.

5. The transistor according to claim 4, wherein the gate electrode extends to the bottom surface of the tubular structure through the opening of the tubular structure, and is insulated from the tubular structure through a gate insulation layer.

6. The transistor according to claim 1, wherein the first electrode and the second electrode are located in a same conductive layer parallel to the substrate; and
an outer surface of a channel region of the semiconductor layer is in a same horizontal plane as an outer surface of an adjacent first electrode and/or second electrode.

7. The transistor according to claim 1, wherein a material of the semiconductor layer is a metal oxide semiconductor material.

8. A 3D stacked semiconductor device, comprising:
a word line; and
a plurality of memory cells, distributed in different layers and stacked periodically along a direction perpendicular to a substrate; wherein each layer comprises a plurality of columns of memory cells, and a memory cell comprises a transistor; the transistor comprises a first electrode, a second electrode, a semiconductor layer arranged between the first electrode and the second electrode, and a gate electrode; the first electrode and the second electrode are separated in a first direction parallel to the substrate; the gate electrode comprises a side wall and two end surfaces, one end surface of the two end surfaces is configured to be connected with the word line, and the other end surface of the two end surfaces extends into a hollow annular semiconductor layer; and an extension direction of the gate electrode intersects with an extension direction of the word line.

9. The 3D stacked semiconductor device according to claim 8, wherein the end surface of the gate electrode extending into the semiconductor layer is surrounded by the semiconductor layer.

10. The 3D stacked semiconductor device according to claim 9, wherein the semiconductor layer surrounding the gate electrode forms a hollow tubular structure; the tubular structure has a side surface, a bottom surface and an opening, wherein the side surface comprises two separated electrode contact regions, which are respectively in contact with the first electrode and the second electrode, and a region of the side surface and the bottom surface of the tubular structure located between the first electrode and the second electrode is a channel region; and
the gate electrode extends to the bottom surface of the tubular structure through the opening of the tubular structure.

11. The 3D stacked semiconductor device according to claim 8, wherein the gate electrode extends along a second direction parallel to the substrate, and the first direction intersects with the second direction;
the word line extends along a direction perpendicular to the substrate; and gate electrodes of transistors of a column of memory cells located in different layers are connected with a same word line; and
the 3D stacked semiconductor device further comprises a plurality of bit lines extending along the second direction; and transistors of a column of memory cells located on a same layer and arranged along the second direction are connected to a same bit line.

12. The 3D stacked semiconductor device according to claim 8, wherein the gate electrode extends along a second direction parallel to the substrate, and the first direction intersects with the second direction;
the word line extends along the second direction; gate electrodes of transistors of a column of memory cells located in a same layer and arranged along the second direction are connected with a same word line; and
the 3D stacked semiconductor device further comprises a plurality of bit lines extending along a direction perpendicular to the substrate; and transistors of a column of memory cells located in different layers are connected to a same bit line.

13. A method for manufacturing a 3D stacked semiconductor device, wherein the 3D stacked semiconductor device comprises: a word line; and a plurality of memory cells distributed in different layers and stacked periodically along a direction perpendicular to a substrate; each layer comprises a plurality of columns of memory cells, and a memory cell comprises a transistor; the transistor comprises a first electrode, a second electrode, a semiconductor layer arranged between the first electrode and the second electrode, and a gate electrode; the first electrode and the second electrode are separated in a first direction parallel to the substrate; the gate electrode extends along a second direction in a plane parallel to the substrate, and the gate electrode comprises a sidewall extending along the second direction and two end surfaces, one end surface is configured to be connected with a word line, and the other end surface extends into a hollow annular semiconductor layer; the first direction intersects with the second direction; an extension direction of the gate electrode intersects with an extension direction of the word line;
the method comprises:
forming a first electrode and a second electrode of a transistor on the substrate;
forming a bit line connected to a plurality of second electrodes;
forming a hollow annular semiconductor layer between the first electrode and the second electrode, and a gate electrode with one end surface extending into the semiconductor layer; and
forming a word line connected to the other end surfaces of a plurality of gate electrodes after the gate electrodes are formed, and making an extension direction of the word line be intersected with an extension direction of the gate electrodes.

14. The method for manufacturing a 3D stacked semiconductor device according to claim 13, wherein forming the first electrode and the second electrode of the transistor on the substrate, and forming the bit line connected to the plurality of second electrodes, comprises:
sequentially and alternately depositing first insulation layers and second insulation layers on the substrate;
performing a patterning etching on the first insulation layers and the second insulation layers, wherein a patterned first insulation layer and a patterned second insulation layer comprise a dummy bit line region extending along the second direction, a dummy electrode region extending from a side of the dummy bit line region towards the first direction, a dummy channel and gate region extending from a side of the dummy electrode region towards the second direction; wherein the dummy electrode region comprises a first electrode region located between two adjacent dummy channel and gate regions, and a second electrode region located between the dummy bit line region and the dummy channel and gate region; one end of the dummy channel and gate region is connected with the dummy electrode region;
etching to remove a patterned second insulation layer of the first electrode region, obtaining a first electrode groove, and forming the first electrode in the first electrode groove; and
etching to remove patterned second insulation layers of the second electrode region and the dummy bit line region, obtaining a second electrode groove and a bit line groove, respectively, and forming the second electrode and the bit line connected to the second electrode in the second electrode groove and the bit line groove, respectively.

15. The method for manufacturing a 3D stacked semiconductor device according to claim 14, wherein two ends of the dummy electrode region are connected to two adjacent dummy bit line regions, respectively, and each dummy electrode region is connected to two dummy channel and gate regions; the memory cell further comprises a capacitor, and the capacitor comprises a third electrode and a fourth electrode;
etching to removing the patterned second insulation layer of the first electrode region, obtaining the first electrode groove, and forming the first electrode in the first electrode groove, and the forming process of the capacitor comprise:
filling a stacked structure formed by the patterned first insulation layer and the patterned second insulation layer by using the first insulation layer;
etching the stacked structure along a direction towards the substrate, forming a first groove in the first electrode region extending along the second direction and penetrating through each patterned second insulation layer, wherein the first groove separates the first electrode region into two portions, and the first groove exposes end surfaces of separated first electrode regions on both sides;
laterally etching the patterned second insulation layer on both sides of the first groove, to remove the patterned second insulation layer of the first electrode region, and obtaining first electrode grooves on both sides of the first groove;
depositing a first conductive layer in the first electrode groove;
etching the first insulation layer on both sides of the first groove to expose a side surface, with a set depth, of the first conductive layer; wherein an exposed region of the first conductive layer is a third electrode of the capacitor, and an unexposed region is the first electrode of the transistor; and
sequentially forming a dielectric layer and a fourth electrode of the capacitor on a surface of the third electrode.

16. The method for manufacturing a 3D stacked semiconductor device according to claim 15, wherein etching to remove the patterned second insulation layers of the second electrode region and the dummy bit line region, obtaining the second electrode groove and the bit line groove, respectively, and forming the second electrode and the bit line connected to the second electrode in the second electrode groove and the bit line groove, respectively, comprises:
etching the patterned first insulation layer and second insulation layer distributed in a stacked mode along a direction towards the substrate, forming an initial bit line groove in the dummy bit line region extending along the second direction and penetrating through each patterned second insulation layer, laterally etching the patterned second insulation layers on both sides of the initial bit line groove to remove the patterned second insulation layers of the second electrode region and the dummy bit line region, wherein a portion of a sidewall of the initial bit line groove extends into the patterned second insulation layer to obtain a bit line groove located in the dummy bit line region and a second electrode groove located in the second electrode region;
depositing a second conductive layer in the bit line groove and the second electrode groove, and forming a second electrode in the second conductive layer located in the second electrode groove; and
etching the second conductive layer located in the bit line groove along a direction towards the substrate, forming a second groove extending along the second direction and penetrating through each layer bit line groove, wherein the second groove separates the second conductive layer in the bit line groove into two bit lines, and each bit line is connected with a separated column of second electrodes along the second direction; and depositing the first insulation layer in the second groove.

17. The method for manufacturing a 3D stacked semiconductor device according to claim 16, wherein forming the hollow annular semiconductor layer between the first electrode and the second electrode, and the gate electrode with one end surface extending into the semiconductor layer, and after the gate electrode is formed, forming the word line connected to the other end surfaces of the plurality of the gate electrodes, and making the extension direction of the word line be intersected with the extension direction of the gate electrode, comprises:
etching a patterned first insulation layer and a patterned second insulation layer on a side of the dummy channel and gate region away from the dummy electrode region, forming a word line groove penetrating through each patterned second insulation layer on the side of the dummy channel and gate region away from the dummy electrode region, wherein the word line groove exposes an end surface of the patterned second insulation layer;
etching the patterned second insulation layer in the word line groove to remove a patterned second insulation layer in the whole dummy channel and gate region, and obtaining a channel groove located in the dummy channel and gate region and connected with one end of the dummy electrode region, and a gate electrode groove located between the channel groove and the word line groove;
sequentially forming a semiconductor layer and a third insulation layer on inner walls of the word line groove, the gate electrode groove and the channel groove, and filling a third conductive layer in remaining spaces of the word line groove, the gate electrode groove and the channel groove; and
etching to remove a third conductive layer and a third insulation layer in the word line groove, etching to remove a semiconductor layer in the word line groove and the gate electrode groove, and depositing a third insulation layer on an inner wall of the gate electrode groove, and depositing a third conductive layer in the word line groove; wherein the semiconductor layer retained in the channel groove serves as the semiconductor layer of the transistor, the third conductive layer located in the gate electrode groove and the channel groove serves as the gate electrode of the transistor, the third conductive layer located in the word line groove serves as the word line, and the third insulation layer located in the channel groove and the gate electrode groove forms a gate insulation layer that insulates the semiconductor layer from the gate electrode and the word line.

18. An electronic device, comprising a transistor according to claim 1.

19. An electronic device, comprising the 3D semiconductor device according to claim 8.

20. The transistor according to claim 3, wherein a cross section of the semiconductor layer surrounding the gate electrode is U-shaped or two separated lines.
